(19) United States
(12) Patent Application Publication
(10) Pub. No.: US 2003/0101936 A1
(43) Pub. Date: Jun. 5, 2003

(54) Plasma reaction apparatus

(75) Inventor: Dong Hoon Lee, Masan city (KR)

Correspondence Address: LEE & HONG, 801 SOUTH FIQUEROA STREET, 14TH FLOOR, LOS ANGELES, CA, 90017, US

(73) Assignee: Dong Hoon Lee and Yong Moo Lee

(21) Appl. No.: 10/285,101

(22) Filed: Oct. 31, 2002

(30) Foreign Application Priority Data
Dec. 4, 2001 (KR) 2001-0076156
Apr. 8, 2002 (KR) 2002-0019015

(51) Int. Cl. C23C 16/00

(52) U.S. Cl. 118/723 E

(57) ABSTRACT

The present invention provides a plasma reaction apparatus capable of producing ozone water, alkaline water, or acid water at a high efficiency and low power consumption during discharge in water. The invention also achieves a decrease in the molecular weight of oil in a short time through stable glow discharge during discharge in the oil. Accordingly, there is provided a plasma reaction apparatus for causing discharge to occur by using liquid such as water and oil, or gas as a medium and by applying a voltage to two electrodes disposed within a reactor. The apparatus comprises first and second electrodes formed on both sides with a discharge region interposed therebetween, and a reactive catalytic layer formed on at least one of the first and second electrodes that face the discharge region. The apparatus is effective in decomposition, purification and neutralization of harmful liquid and gaseous materials.

### BACKGROUND OF THE INVENTION

1. Field of the Invention

The present invention relates to a plasma reaction apparatus, and more particularly, to a plasma reaction apparatus by which fuel gasification and conversion into high value-added products can be made to various oils and waste oils, high-efficiency discharge can be achieved with low power consumption, dioxin generated from an incinerator, volatile organic compounds and the like can be treated, and chlorofluorocarbon (CFC) based non-degradable materials that are global warming substances can be treated using non-thermal plasma.

2. Description of the Prior Art

Environmental pollution such as air and water pollution due to the rapid growth of industry gradually becomes an urgent issue. Accordingly, regulation and administratively guidance on the environmental pollution are made in all the countries of the world in order to protect the environments. In this regard, there is an urgent need to prepare measures for eliminating pollutants that are the causes of the environmental pollution or for reducing sources of the pollutants.

Nevertheless, there is still a growing tendency for synthetic detergents to be used more and more. According to statistical data, it was reported that production of the synthetic detergents exceeded production of soaps since the late 1980's in Korea.

In particular, the indiscreet and excessive use of the synthetic detergents caused a great anxiety about the water pollution. Recently, although the past anxiety about the water pollution considerably died down owing to a reduction in environmental loads and technology development for functional improvement of the synthetic detergents, it is still known that the synthetic detergents are a major cause of the water pollution.

Therefore, in order to prevent any surfactant-based detergents from causing the water pollution problem, the sewage should be subjected to a purification process in a sewage treatment plant before it is drained into natural rivers. However, since a sewage treatment ratio is still low at present, it is impossible to completely avoid the water pollution such as foam generation, eutrophication and biodegradation in the rivers due to the use of the synthetic detergents.

Accordingly, there has been proposed the so-called detergent-free cleaning method using electrolyzed water as a sterilizing/cleaning liquid instead of the synthetic detergents. In the detergent-free cleaning method, water containing electrolytes is electrolyzed in order to utilize a protein skimming activity of alkaline electrolyzed water and a sterilization activity of acid electrolyzed water. The electrolyzed water has recently attracted considerable attention in that it can be expected to replace conventional chemicals or surfactants.

However, if such a type of detergent is intended to be applied to washing of clothes or dishes, the detergent should have cleaning power at least equal to or higher than that of conventional surfactants. In this connection, there is a need for determining which property should be primarily controlled to prepare such a detergent in view of a cleaning mechanism.

Further, in view of sewage with the detergent contained therein after completion of the washing of clothes and dishes, the detergent should have excellent waste-water treatability, i.e. ability to handle the sewage to such an extent that the sewage is allowed to be drained into living environments without any special treatments thereof.

In the conventional detergent-free cleaning method, various types of voltages having arbitrary frequencies, i.e. AC voltage, DC voltage and pulsed voltage, are applied to two electrodes to weaken the dielectric strength of water and thus to allow electrons or electric charges to flow through the water. Accordingly, the water is electrolyzed by using electric power consumed at this time. Here, the electrodes to which the voltages are applied are mainly composed of platinum. The reason why the platinum (or silver) is suitable for the materials of the electrodes immersed in the water is that ozone generated during the electrolysis of the water has strong oxidizing power.

However, since the conventional detergent-free cleaning method is performed in such a manner that an electric current is applied directly to the water to convert the water into ozone water, alkaline water, acid water or the like, there is a disadvantage in that much energy is consumed in heating the water rather than in ionizing the water. If high energy is continuously applied to the electrodes, there is another disadvantage in that the electrodes are excessively worn away. Since electric discharge occurs between the electrodes directly in the water, such an electrode wear phenomenon becomes remarkable due to un-uniformity of an electric field.

Meanwhile, in a conventional oil treatment, an alternating current, a direct current or a pulsed current is applied to a plate-type reactor and the electrodes comprise helical metal electrodes. The discharge is in the form of streamer discharge which is not glow discharge (e.g., discharge in a fluorescent lamp) and utilizes a very unstable discharge phenomenon just before flashover (dielectric breakdown) occurs.

However, although such an oil treatment technique can achieve a slight decrease in a molecular weight of the oil by the strong streamer, a lot of carbonized residues are produced. Further, since local discharge due to electric-field concentration occurs in a discharge space, the electrodes are extremely worn out.

Moreover, since the discharge occurs directly between the electrodes and the oil is insulation material, the strong streamer discharge instantly occurs without occurrence of the smooth glow discharge. Accordingly, there is a problem in that a small variation in the voltage results in dielectric breakdown.

### SUMMARY OF THE INVENTION

The present invention is conceived to solve the problems in the prior art. An object of the present invention is to provide a plasma reaction apparatus capable of producing ozone water, alkaline water or acid water at a high efficiency and low power consumption during discharge in water, and achieving a decrease in the molecular weight of oil through stable glow discharge during discharge in the oil for treatment of the oil.

Another object of the present invention is to provide a plasma reaction apparatus capable of converting various kinds of oils and waste oils into high value-added products or allowing them to be recycled.

A further object of the present invention is to provide a low power consumption and high efficiency type plasma reaction apparatus capable of treating dioxin discharged in a great amount from volatile organic compounds, an incinerator or the like, and treating chlorofluorocarbon (CFC) based non-degradable materials, which are utilized as a refrigerant for semiconductor processes and refrigerators but is a global warming substance, by using non-thermal plasma.

According to one embodiment of the present invention for achieving the above objects, there is provided a plasma reaction apparatus for causing discharge to occur by using water or oil as a medium and by applying a voltage to two electrodes disposed in a reactor. The plasma reaction apparatus comprises first and second electrodes formed on both sides with a discharge region interposed therebetween, and a reactive catalytic layer formed on at least one of the first and second electrodes that face the discharge region.

The plasma reaction apparatus according to the present invention prevents the lives of the electrodes from being shortened due to strong streamer discharge that is locally generated on surfaces of the electrodes during the discharge, and allows an electric field to be uniformly distributed throughout electrodes. Accordingly, it is possible to minimize electrode wear due to an electric field stress that may be generated during the discharge.

That is, the plasma reaction apparatus according to the present invention maximizes a discharge efficiency while minimizing the electrode wear due to an electric field stress, which may be generated during the discharge, by forming the reactive catalytic layer composed of paraelectrics between the two electrodes.

Further, the discharge efficiency can be maximized by optimizing the size of the reactive catalytic layer of the paraelectrics formed between the two electrodes so as to minimize the electrode wear due to the electric filed stress that may be generated during the discharge.

Moreover, the electrode wear due to the electric field stress that may be generated during the discharge can be minimized by optimizing shapes of the two electrodes.

Furthermore, the discharge efficiency can be maximized by applying a magnetic field in a direction perpendicular to a direction of the electric field.

The plasma reaction apparatus according to the present invention can be applied to the discharge to be performed in water, oil, or gas. For the convenience of description, the plasma reaction apparatus will be separately explained with respect to the underwater discharge and the discharge in the oil, respectively.

The plasma reaction apparatus according to the present invention maximizes the discharge efficiency by forming a discharging catalytic layer having an insulation property on at least one of the two electrodes and causing a catalytic reaction to occur on the discharging catalytic layer. Further, a uniform plasma state or plasma light is caused to be produced throughout between the electrodes, i.e. the entire discharge region in the water, so that an efficiency of generating the ozone water, alkaline water or acid water per unit energy can be maximized.

At this time, the discharging catalytic layer has a structure which may be a laminated structure constructed by sequentially stacking an insulation layer composed of amorphous material capable of completely insulating the surface of the electrode and a crystalline dielectric layer one above another, or a single-layered structure composed of only any one of the amorphous insulation layer and the crystalline dielectric layer.

The discharging catalytic layer preferably has, on its surface, protruding features such as elongated triangles, pointed peaks, or gently-sloping brush needles. At this time, the protruding features may come into contact with the opposite electrode. In this case, since the discharge is generated in such a manner that electrons produced at the protruding features during the discharge diffuse along and throughout the surface of the discharging catalytic layer, it is possible to solve a problem of electric field concentration that the discharge locally occurs at a portion of the surface. Therefore, the electrode wear can be minimized as compare with conventional discharge occurring directly between the electrodes.

Meanwhile, the amorphous insulation layer is composed of insulation material having a dielectric constant within a range of a few to several hundreds, preferably material falling within a group consisting of glass, quartz, Pyrex, and the like. It is preferred that the crystalline dielectric layer be composed of paraelectrics such as Al₂O₃, ZrO₂ or TiO₂, or ferroelectrics such as material falling within a BaTiO₃ group.

Since at least one of the two electrodes is completely insulated by the insulation layer in such a way, dielectric discharge occurs from the crystalline dielectric layer when a voltage is applied to the electrodes. Further, a strong, partial electric field is generated between dielectric grains constituting the crystalline dielectric layer, the plasma can be more easily generated in the water. Thus, it is possible to minimize the electrode wear due to un-uniformity of the electric field produced between the electrodes.

A plasma reaction apparatus according to another embodiment of the present invention has the reactive catalytic layer formed on at least one of the two electrodes, and an additional reactive catalytic layer composed of pellet-type paraelectrics or pellet-type ferroelectrics formed in a space between the two electrodes, thereby maximizing the discharge efficiency by means of the catalytic reaction on the discharging catalytic layer. That is, a uniform plasma state or plasma light is caused to be produced throughout the discharge region between the electrodes, so that the efficiency of generating the ozone water, alkaline water or acid water per unit energy can be maximized.

At this time, the discharging catalytic layer has a structure which may be a laminated structure constructed by sequentially stacking an insulation layer composed of amorphous material capable of completely insulating the surface of the electrode and a crystalline dielectric layer one above another, or a single-layered structure constructed only by either the amorphous insulation layer or the crystalline dielectric layer.

The insulation layer is composed of insulation material having a dielectric constant within a range of a few to several hundreds, preferably material falling within a group consisting of glass, quartz, Pyrex, and the like. It is preferred that the crystalline dielectric layer be composed of paraelectrics such as Al₂O₃, ZrO₂ or TiO₂, or ferroelectrics such as material falling within a BaTiO₃ group.

By forming the additional reactive catalytic layer composed of the pellet-type paraelectrics or pellet-type ferroelectrics between the two electrodes in such a way, when air or oxygen in the form of small bubbles is injected into the reaction apparatus and a voltage is then applied to the apparatus, a triple point is obtained among the air, the reactive catalytic layer and the pellet-type paraelectrics (or ferroelectrics). Accordingly, the strength of the electric field is increased due to the electric field concentration at the triple point and thus stronger discharge can be generated.

### BRIEF DESCRIPTION OF THE DRAWINGS

The above and other objects and features of the present invention will become apparent from the following description of preferred embodiments given in conjunction with the accompanying drawings, in which:

FIG. 1a is a view showing the constitution of a plasma reaction apparatus for discharge in both water and oil, according to a first embodiment of the present invention;

FIG. 1b is a sectional view taken along line I-I′ of FIG. 1a;

FIG. 1c is an enlarged view showing a portion of FIG. 1b;

FIG. 1d is a perspective view of the plasma reaction apparatus for discharge in both water and oil, according to the first embodiment of the present invention;

FIGS. 2a and 2b are views showing the constitution of a plasma reaction apparatus for discharge in both water and oil, according to a second embodiment of the present invention;

FIG. 3 is a view showing the constitution of a plasma reaction apparatus for discharge in both water and oil, according to a third embodiment of the present invention;

FIG. 4 is a view showing the constitution of a plasma reaction apparatus for discharge in both water and oil, according to a fourth embodiment of the present invention;

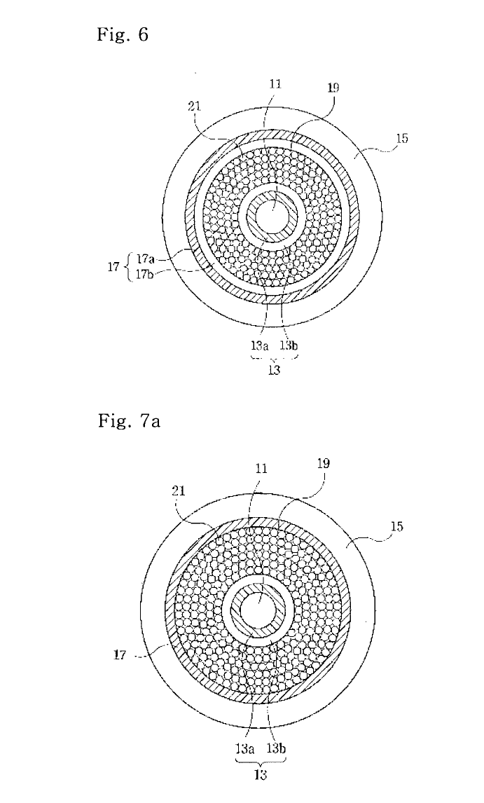

FIGS. 5a and 5b are views showing the constitution of a plasma reaction apparatus for discharge in both water and oil, according to a fifth embodiment of the present invention;

FIG. 6 is a view showing the constitution of a plasma reaction apparatus for discharge in both water and oil, according to a sixth embodiment of the present invention;

FIGS. 7a and 7b are views showing the constitution of a plasma reaction apparatus for discharge in both water and oil, according to a seventh embodiment of the present invention;

FIGS. 8a and 8b are views showing the constitution of a plasma reaction apparatus for discharge in both water and oil, according to an eighth embodiment of the present invention;

FIG. 9 is a view showing the constitution of a plasma reaction apparatus for discharge in both water and oil, according to a ninth embodiment of the present invention;

FIG. 10 is a view showing the constitution of a plasma reaction apparatus for discharge in both water and oil, according to a tenth embodiment of the present invention;

FIG. 11 is a view showing the constitution of a plasma reaction apparatus for discharge in both water and oil, according to an eleventh embodiment of the present invention;

FIGS. 12a to 15b are views showing the constitution of a plasma reaction apparatus for discharge in both water and oil, according to a twelfth embodiment of the present invention;

FIGS. 16 and 17 are comparative views explaining the maximum strength of an electric field in a plasma reaction apparatus according to a thirteenth embodiment of the present invention;

FIGS. 18a to 18c are views explaining the strength of the electric field by pellet sizes according to the thirteenth embodiment of the present invention;

FIGS. 19a to 19c are views illustrating equipotential lines corresponding to FIGS. 18a to 18c;

FIGS. 20a and 20b are views explaining the strength of the electric field in a case where the pellet according to the present invention is shaped in the form of a rhombus;

FIGS. 21a and 21b are views explaining the strength of the electric field depending on dielectric constants of the pellet in the case where the pellet according to the present invention is shaped in the form of a rhombus;

FIGS. 22a to 22d are views explaining an interval between electrodes and an interval between equipotential electrodes according to a fourteenth embodiment of the present invention;

FIGS. 23a and 23b are views explaining the strength of the electric field in a case where pellets composed of paraelectrics and ferroelectrics, respectively, are formed between the two electrodes according to the fourteenth embodiment of the present invention;

FIGS. 24a and 24b are view explaining optimal shapes of the electrode for minimizing electrode wear according to the fourteenth embodiment of the present invention;

FIGS. 25a and 25b are views showing the constitution of a plasma reaction apparatus according to a fifteenth embodiment of the present invention;

FIGS. 26 and 27 are views explaining a motion principle of a charged particle within an electromagnetic field according to the fifteenth embodiment of the present invention;

FIG. 28 is a view showing the constitution of a plasma reaction apparatus according to a sixteenth embodiment of the present invention;

FIGS. 29a to 29d are comparative views explaining discharge patterns when a magnetic filed is applied or not according to the sixteenth embodiment of the present invention; and

FIG. 30 is a view showing the constitution of a plasma reaction apparatus according to a seventeenth embodiment of the present invention.

### DETAILED DESCRIPTION OF THE PREFERRED EMBODIMENTS

Hereinafter, plasma reaction apparatuses according to preferred embodiments of the present invention will be described in detail with reference to the accompanying drawings.

First Embodiment

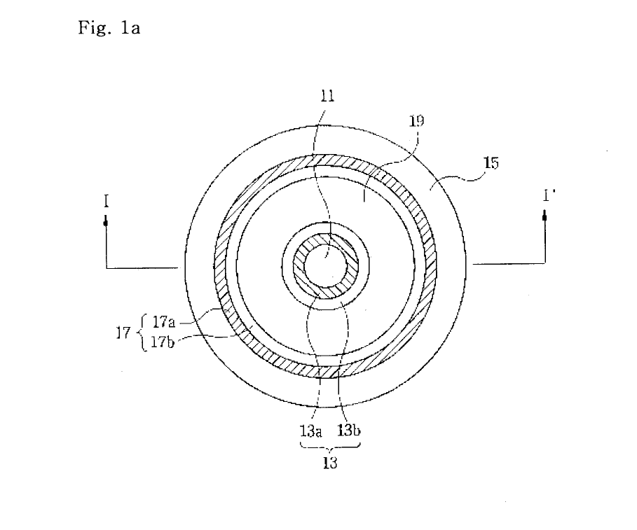

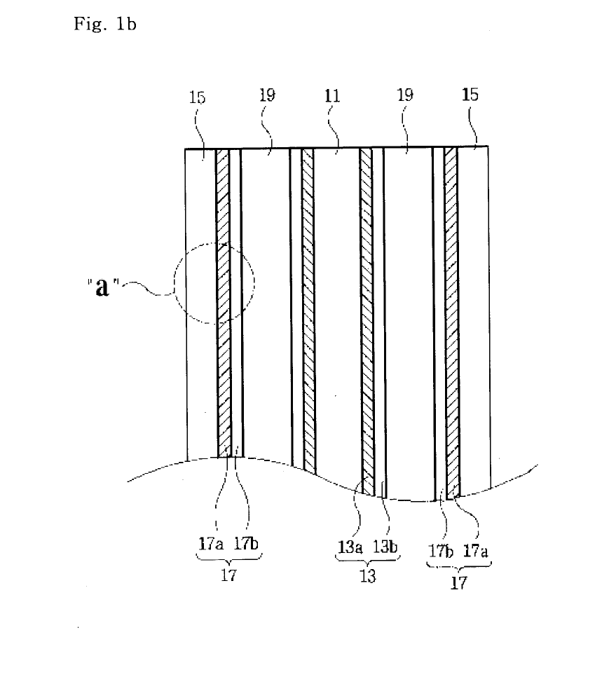

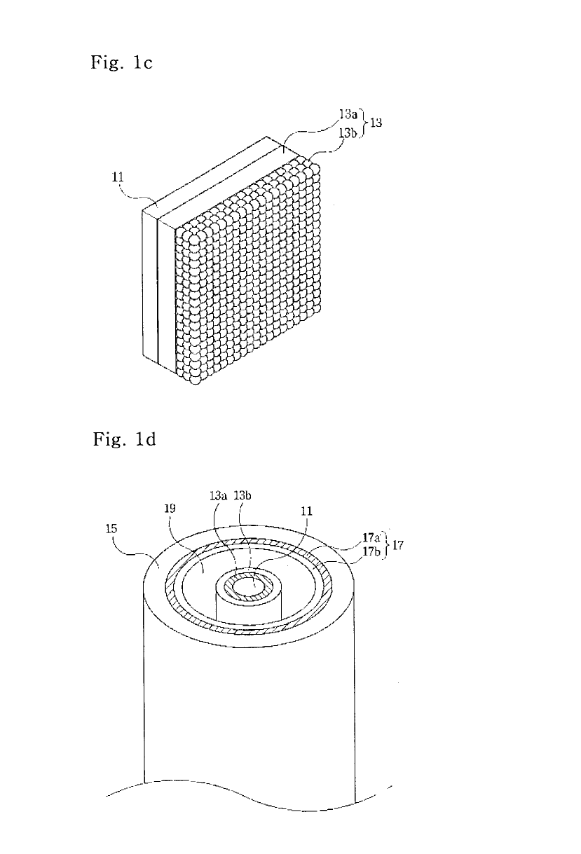

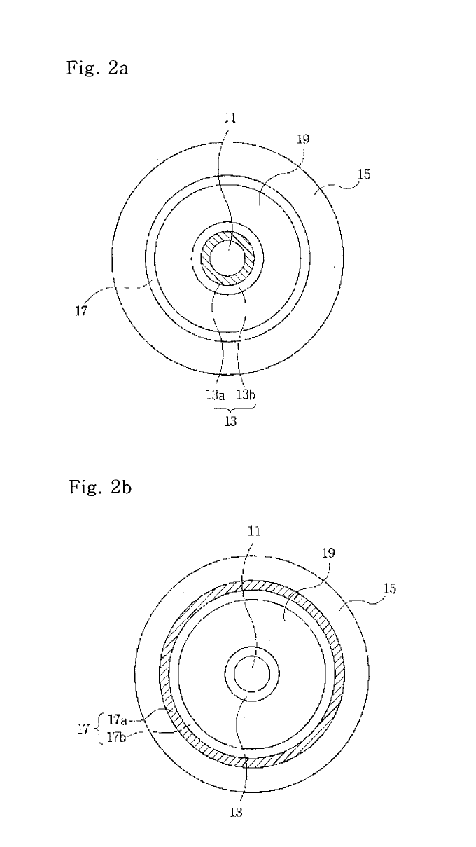

FIGS. 1a to 1d show a plasma reaction apparatus according to a first embodiment of the present invention, wherein FIG. 1a is a front view thereof, FIG. 1b is a sectional view taken along line I-I′ of FIG. 1a, FIG. 1c is an enlarged view showing a portion of FIG. 1b, and FIG. 1d is a perspective view of the plasma reaction apparatus for discharge in water, according to the first embodiment of the present invention.

As shown in the figures, the plasma reaction apparatus for the discharge in the water according to the first embodiment of the present invention is a coaxial cylinder type, and comprises a first cylindrical electrode 11, a first reactive catalytic layer 13 which is formed along and on an outer periphery of the first electrode 11 and constructed by sequentially stacking an insulation layer 13a composed of amorphous material and a crystalline dielectric layer 13b one above another, a second electrode 15 formed to surround the first reactive catalytic layer 13 with a predetermined interval therebetween, and a second reactive catalytic layer 17 which is formed along and on an inner periphery of the second electrode 15 and constructed by sequentially stacking an insulation layer 17a composed of amorphous material and a crystalline dielectric layer 17b one above another.

At this time, the space between the first and second reactive or discharging catalytic layers 13, 17 is a passage through which a medium flows, i.e. a water channel 19. The amorphous insulation layers 13a, 17a are preferably made of material falling within a group consisting of glass, quartz, and Pyrex. The crystalline dielectric layers 13b, 17b are preferably made of paraelectrics such as Al₂O₃, ZrO₂ or TiO₂, or ferroelectrics such as material falling within a BaTiO₃ group.

Platinum (Pt) is used as the material for composing the first and second electrodes 11, 15 to which a direct current, or any one of alternating currents or pulsed currents having various frequencies is applied. It is preferred that a low frequency lower than a range of several hundreds Hz be employed in case of the discharge in the water, i.e. underwater discharge, and a high frequency higher than a range of few dozens Hz, pps be employed in case of the discharge in oil.

In the plasma reaction apparatus according to the first embodiment of the present invention constructed as such, since the first and second reactive catalytic layers 13, 17 having laminated structures in which the amorphous insulation layers 13a, 17a and the crystalline dielectric layers 13b, 17b are stacked one above another on the surfaces of the first and second electrodes 11, 15, respectively, the strength of an electric field in the interiors and surfaces of the first and second reactive catalytic layers 13, 17 is increased and thus blue plasma light is generated when the direct current, alternating current or pulsed current is applied thereto.

Therefore, upon generation of the discharge, stable discharge is made by means of a high electric field and a low current rather than thermal discharge due to a conductive characteristic of the water. Accordingly, alkaline water, acid water or ozone water can be obtained at high efficiency and low power consumption.

In other words, as compared with a prior art in which only water exists in the discharge space between the first and second electrodes 11, 15, the electric filed can be more easily generated within the water by forming the first and second discharging catalytic layers 13, 17 on the surfaces of the first and second electrodes 11, 15, respectively. As a result, since a stronger electric field can be instantaneously applied to molecules of the water, the alkaline water, acid water or ozone water can be obtained at high efficiency. Further, the stable discharge characteristic rather than the thermal discharge can be obtained based on the high electric field and low current, so that the reaction apparatus can be stably driven with high reliability and accuracy. Moreover, since the first and second electrodes 11, 15 do not come into direct contact with the water, electrode wear can be minimized.

Referring to FIG. 1c, there is exemplarily shown the structure of the first reactive catalytic layer 13 in which the amorphous insulation layer 13a and the crystalline dielectric layer 13b are stacked one above another.

Second Embodiment

A second embodiment of the present invention is a modification of the first embodiment. One of the two electrodes is provided with the reactive catalytic layer having the laminated structure in which the amorphous insulation layer and the crystalline dielectric layer are stacked one above another, and the other electrode is provided with a reactive catalytic layer having a single-layered structure constructed by means of one crystalline dielectric layer.

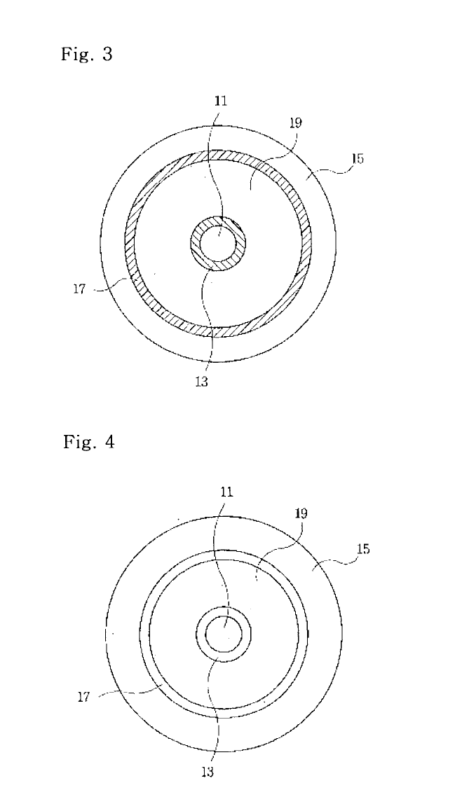

As shown in FIG. 2a, the first reactive catalytic layer 13 having the laminated structure in which the amorphous insulation layer 13a and the crystalline dielectric layer 13b are sequentially stacked one above another may be formed on the first electrode 11, and the second reactive catalytic layer 17 composed of crystalline dielectrics may be formed on the second electrode 15. Alternatively, as shown in FIG. 2b, the first reactive catalytic layer 13 having the single-layered structure composed of the crystalline dielectrics may be formed on the first electrode 11, and the second reactive catalytic layer 17 having the laminated structure in which the amorphous insulation layer 17a and the crystalline dielectric layer 17b are sequentially stacked one above another may be formed on the second electrode 15.

At this time, the amorphous material for composing the insulation layers 13a, 17a is preferably material falling within the group consisting of glass, quartz, and Pyrex. The crystalline dielectric layers 13b, 17b are preferably made of the paraelectrics such as Al₂O₃, ZrO₂ or TiO₂, or the ferroelectrics such as material falling within the BaTiO₃ group.

Alternatively, if only the crystalline dielectric layers 13b, 17b are formed on the electrodes, respectively, any crystalline dielectric layers can be employed as far as they have no porosity so that the water cannot come into contact with the electrodes and their surfaces have an embossing texture, a pointed peak texture, or a smooth texture so that the discharge can easily occur.

Third Embodiment

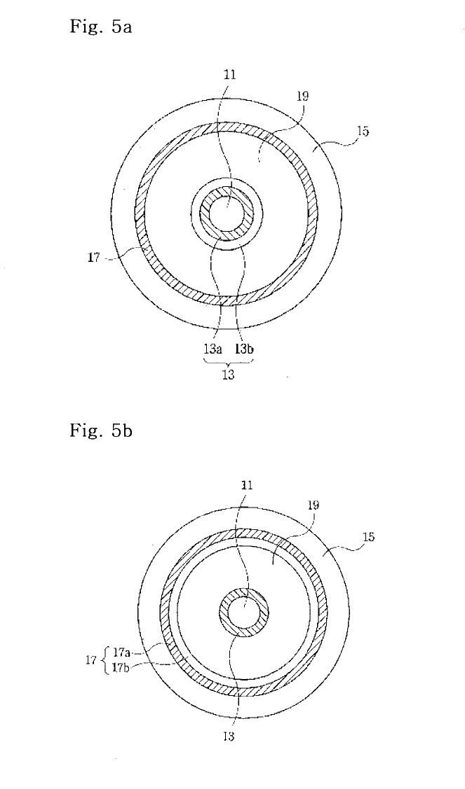

In a plasma reaction apparatus according to a third embodiment of the present invention, the reactive catalytic layer is composed of only insulation material. That is, as shown in FIG. 3, the plasma reaction apparatus comprises the first cylindrical electrode 11, the first reactive catalytic layer 13 which is formed along and on the outer periphery of the first electrode 11 and has a single-layered structure composed of amorphous insulation material, the second electrode 15 formed to surround the first reactive catalytic layer 13 with a predetermined interval therebetween, and the second reactive catalytic layer 17 which is formed along and on the inner periphery of the second electrode 15 and has a single-layered structure composed of the amorphous insulation material.

Here, it is preferred that the amorphous insulation material for the first and second reactive catalytic layers 13, 17 be material falling within the group consisting of glass, quartz, and Pyrex.

Moreover, although not shown in the figures, the reactive catalytic layer composed of the amorphous insulation material may be formed on only either one of the first and second electrodes. That is, it is possible to form only the first reactive catalytic layer 13 composed of the amorphous insulation material on only the outer periphery of the first electrode 11, or only the second reactive catalytic layer 17 composed of the amorphous insulation material on only the inner periphery of the second electrode 15.

Fourth Embodiment

In a plasma reaction apparatus according to a fourth embodiment of the present invention, the reactive catalytic layer is constructed by the crystalline dielectric layer unlike the third embodiment.

That is, although the reactive catalytic layer in the third embodiment is composed of the amorphous insulation material, the reactive catalytic layer in the fourth embodiment can be constructed by any crystalline dielectric layers composed of the paraelectrics such as Al₂O₃, ZrO₂ or TiO₂, or the ferroelectrics such as material falling within the BaTiO₃ group as far as they have no porosity so that the water cannot come into contact with the electrodes and their surfaces have an embossing texture or a pointed peak texture so that the discharge can easily occur.

In other words, the plasma reaction apparatus according to the fourth embodiment of the present invention comprises the first cylindrical electrode 11, the first reactive catalytic layer 13 which is formed along and on the outer periphery of the first electrode 11 and composed of the crystalline dielectrics, the second electrode 15 formed to surround the first reactive catalytic layer 13 with a predetermined interval therebetween, and the second reactive catalytic layer 17 which is formed along and on the inner periphery of the second electrode 15 and composed of the crystalline dielectrics.

At this time, the first and second reactive catalytic layers 13, 17 may be constructed by any crystalline dielectric layers as far as they have no porosity so that the water in the channel 19 cannot come into contact with the first and second electrodes 11, 15 and their surfaces have an embossing texture, a pointed peak texture, or a smooth texture so that the discharge can easily occur.

Moreover, although not shown in the figures, it is possible to form the reactive catalytic layer composed of the crystalline dielectrics on only either one of the first and second electrodes 11, 15 without forming the reactive catalytic layer on the other electrode.

That is, it is possible to form only the first reactive catalytic layer 13 having the single-layered structure composed of the crystalline dielectrics on only the outer periphery of the first electrode 11 without forming a reactive catalytic layer on the inner periphery of the second electrode 15, or only the second reactive catalytic layer 17 having the single-layered structure composed of the crystalline dielectrics on only the inner periphery of the second electrode 15 without forming a reactive catalytic layer on the outer periphery of the first electrode 11.

Fifth Embodiment

A plasma reaction apparatus for discharge in the water, according to a fifth embodiment of the present invention is configured in such a manner that the reactive catalytic layer having the laminated structure constructed by sequentially stacking an insulation layer composed of amorphous material and a crystalline dielectric layer one above another is formed on either one of the two electrodes and the reactive catalytic layer having the single-layered structure composed of the amorphous insulation material is formed on the other electrode.

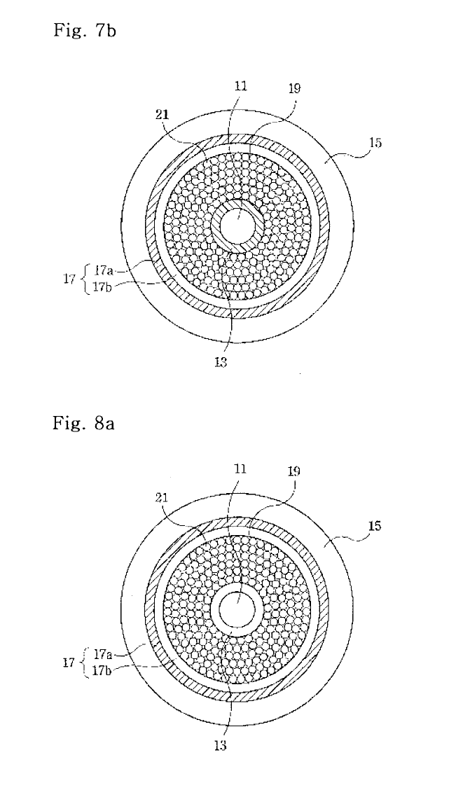

That is, as shown in FIG. 5a, the plasma reaction apparatus comprises the first cylindrical electrode 11, the first reactive catalytic layer 13 which is formed along and on the outer periphery of the first electrode 11 and has the laminated structure constructed by sequentially stacking the insulation layer 13a composed of the amorphous material and the crystalline dielectric layer 13b one above another, the second electrode 15 formed to surround the first reactive catalytic layer 13 with a predetermined interval therebetween, and the second reactive catalytic layer 17 which is formed along and on the inner periphery of the second electrode 15 and has a single-layered structure composed of the amorphous insulation material to be opposite to the first reactive catalytic layer 13.

Further, as shown in FIG. 5b, the first reactive catalytic layer 13 may be constructed to have the single-layered structure composed of the amorphous insulation material and the second reactive catalytic layer 17 may be constructed to have the laminated structure by sequentially stacking the amorphous insulation layer 17a and the dielectric layer 17b composed of the paraelectrics such as Al₂O₃, ZrO₂ or TiO₂, or the ferroelectrics such as material falling within the BaTiO₃ group one above another.

In addition to the above embodiments, those skilled in the art can make other various embodiments. Various embodiments for a structure in which a pellet-type paraelectrics or ferroelectrics layer is formed in the discharge region, i.e. the channel, will be described in detail below.

Sixth Embodiment

A plasma reaction apparatus according to a sixth embodiment of the present invention is constructed such that an additional layer composed of pellet-type paraelectrics or ferroelectrics is formed in the channel. That is, the plasma reaction apparatus according to the sixth embodiment is constructed by adding a third reactive catalytic layer composed of the pellet-type paraelectrics or ferroelectrics to the plasma reaction apparatus for the discharge in the water according to the first embodiment so that the third reactive catalytic layer is formed in the channel that is a region through which the water flows between the first and second reactive catalytic layers.

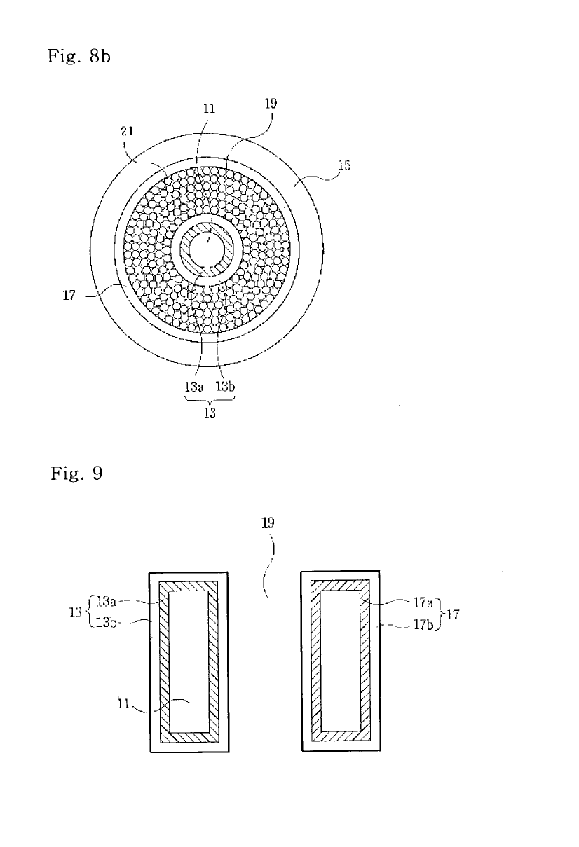

In other words, as shown in FIG. 6, the plasma reaction apparatus according to the sixth embodiment comprises the first cylindrical electrode 11, the first reactive catalytic layer 13 which is formed along and on the outer periphery of the first electrode 11 and constructed by sequentially stacking the insulation layer 13a composed of amorphous material and a crystalline dielectric layer 13b one above another, the second electrode 15 formed to surround the first reactive catalytic layer 13 with a predetermined interval therebetween, the second reactive catalytic layer 17 which is formed along and on the inner periphery of the second electrode 15 and constructed by sequentially stacking the insulation layer 17a composed of amorphous material and the crystalline dielectric layer 17b one above another, and a third reactive catalytic layer 21 composed of the pellet-type paraelectrics or ferroelectrics and formed in the channel 19 between the first and second reactive catalytic layers 13, 17.

When the third reactive catalytic layer 21 composed of the pellet-type paraelectrics or ferroelectrics is formed in the channel 19 in such a way, the strength of a partial electric field applied to the water is several dozen times as strong as that in the underwater discharge using only the water as the medium. Thus, as compared with the case where the third reactive catalytic layer does not exist in view of ionization of the water and productivity per unit time, much alkaline water, ozone water, or acid water can be obtained at much lower power consumption.

Moreover, plasma light is generated in the reaction apparatus by means of the formation of the first, second and third reactive catalytic layers 13, 17 and 21. Ultraviolet rays generated at this time are useful to treat various bacilli such as bacteria and dysentery bacillus together with plasma energy in the water, so that the quality of resultant drinking water can be improved.

Furthermore, since the amorphous insulation layers 13a, 17a completely separate the first and second electrodes 11, 15 from the water, the electrode wear can be minimized and thus the electrodes can be used semi-permanently.

Seventh Embodiment

A seventh embodiment of the present invention is a modification of the sixth embodiment. These embodiments are similar to each other in that the third reactive catalytic layer 21 composed of the pellet-type paraelectrics is formed in the channel 19. However, there is a difference between them in that at least one of the first and second reactive catalytic layers 13, 17 is constructed only by the amorphous insulation layer.

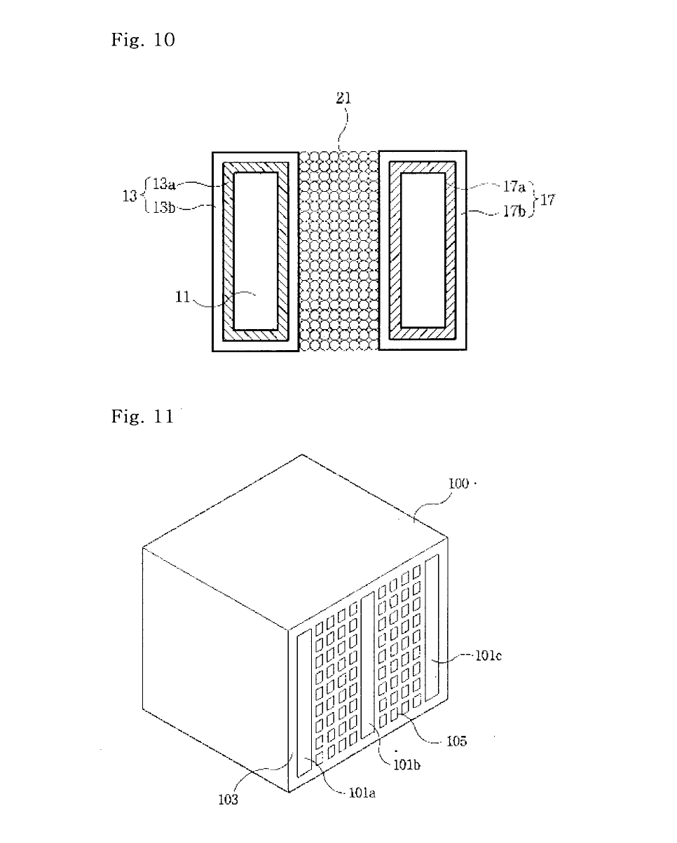

That is, as shown in FIG. 7a, the first reactive catalytic layer 13 may have the laminated structure in which the amorphous insulation layer 13a and the crystalline dielectric layer 13b are sequentially stacked one above another, and the second reactive catalytic layer 17 formed on the second electrode 15 may be composed of the amorphous insulation material. On the contrary, as shown in FIG. 7b, the first reactive catalytic layer 13 may be composed of the amorphous insulation material, and the second reactive catalytic layer 17 may be constructed to have the laminated structure in which the amorphous insulation layer 17a and the crystalline dielectric layer 17b are sequentially stacked one above another.

Eighth Embodiment

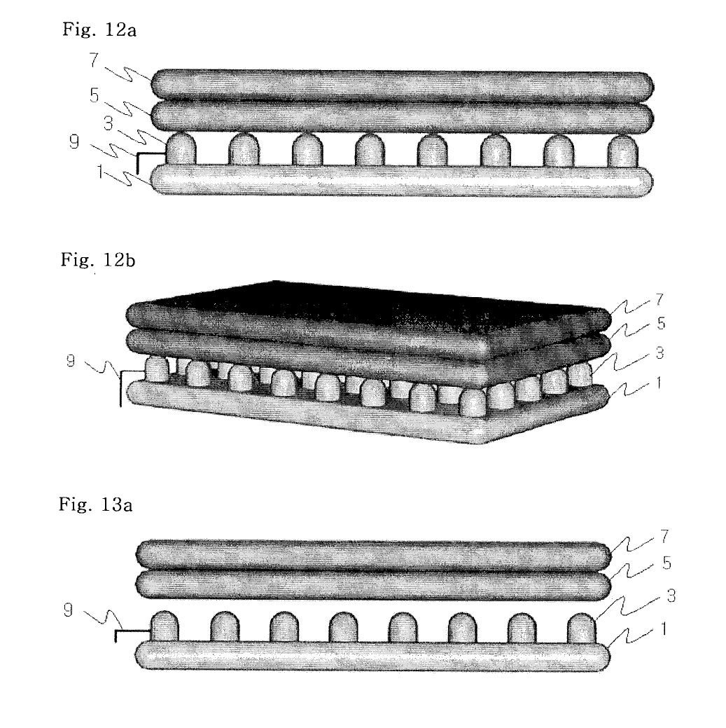

An eighth embodiment of the present invention is also a modification of the seventh embodiment. As shown in FIG. 8a, the first reactive catalytic layer 13 may be composed of the crystalline dielectrics and the second reactive catalytic layer 17 may be constructed to have the laminated structure in which the amorphous insulation layer 17a and the crystalline dielectric layer 17b are sequentially stacked one above another. Alternatively, as shown in FIG. 8b, the first reactive catalytic layer 13 may be constructed to have the laminated structure in which the amorphous insulation layer 13a and the crystalline dielectric layer 13b are sequentially stacked one above another, and the second reactive catalytic layer 17 may be composed of the crystalline dielectrics.

At this time, if the crystalline dielectric layer is formed directly on the electrode without forming the amorphous insulation layer, it is preferred that the crystalline dielectric layer have no porosity so that the water in the channel 19 cannot come into contact with the electrodes and its surface have an embossing texture or a pointed peak texture so that the discharge efficiency can be maximized. Of course, a smooth texture may also be employed.

In addition, although not shown in the figures, the reactive catalytic layer constructed by the amorphous insulation layer or crystalline dielectric layer may be formed on at least one of the first and second electrodes 11, 15 without forming the reactive catalytic layer on the other electrode. Of course, it is apparent that the reactive catalytic layer composed of the pellet-type paraelectrics or ferroelectrics is formed in the channel 19.

In such a way, further various embodiments can be implemented depending on how to combine the materials of the reactive catalytic layers formed on both or either of the two electrodes. Those skilled in the art can easily conceive the embodiments.

Ninth Embodiment

A ninth embodiment of the present invention is characterized in that the electrodes are shaped in the form of a plate, as compared with the previous embodiments.

Each of the plasma reaction apparatuses according to the previous embodiments takes the shape of a cylinder as a whole since it comprises the first cylindrical electrode, the second electrode surrounding the first electrode, and the reactive catalytic layers formed on the outer periphery of the first electrode and the inner periphery of the second electrode. However, the ninth embodiment of the present invention has a parallel plate type configuration of which each plate is configured to correspond to a half of a longitudinal section obtained by axially cutting the above cylindrical reaction apparatus.

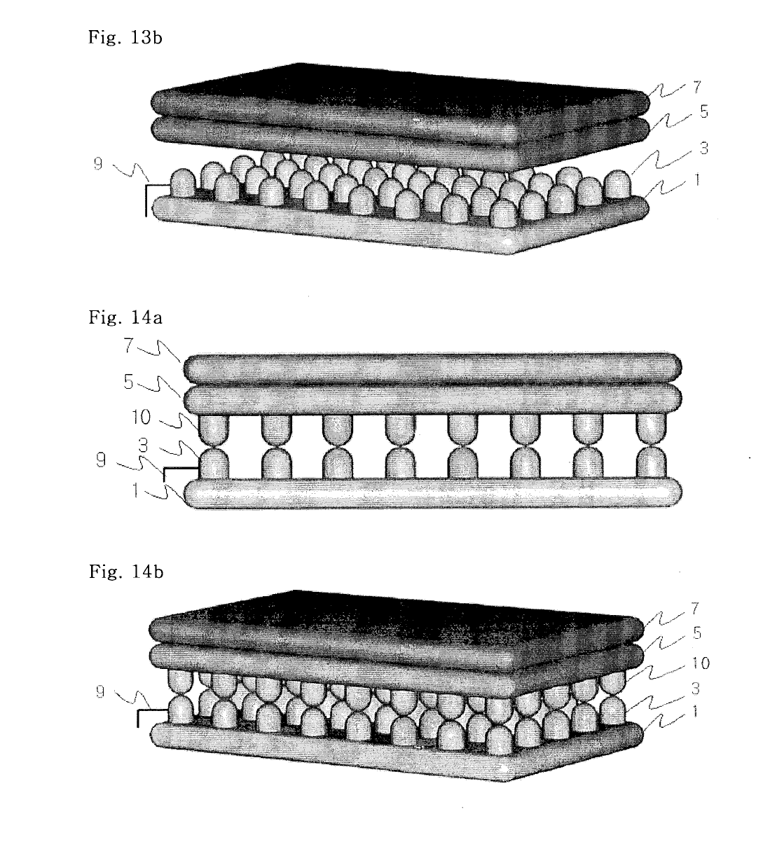

That is, as shown in FIG. 9, the plasma reaction apparatus according to the ninth embodiment comprises the first and second electrodes 11, 15 installed to face each other with a predetermined interval therebetween, and the first and second reactive catalytic layers 13, 17 formed on the surfaces of the first and second electrodes 11, 15 and constructed by sequentially stacking the amorphous insulation layers 13a, 17a and the crystalline dielectric layers 13b, 17b one above another, respectively.

According to the ninth embodiment of the present invention, since the first and second reactive catalytic layers 13, 17 are formed on the surfaces of the first and second electrodes 11, 15, respectively, the strength of an electric field in the interiors and surfaces of the first and second reactive catalytic layers 13, 17 is increased and thus blue plasma light is generated when the direct current source, or any one of alternating or pulsed sources having various frequencies is applied directly thereto. Therefore, upon generation of the discharge, stable discharge is made by means of a high electric field and a low current rather than thermal discharge based on a conductive characteristic of the water.

Accordingly, the alkaline water, acid water or ozone water can be obtained at high efficiency and low power consumption.

In the ninth embodiment of the present invention, it is apparent that the reactive catalytic layers formed on the surfaces of the electrodes can be variously combined in the same ways as the previous embodiments. Therefore, the descriptions of various configurations according to the structures of the reactive catalytic layers on the electrodes can be made with reference to those of the previous embodiments and thus will be omitted.

Tenth Embodiment

When a tenth embodiment of the present invention is compared with the above sixth embodiment for the clarity of description, the electrodes of a plasma reaction apparatus according to the tenth embodiment have a parallel plate type configuration of which each plate is configured to correspond to a half of a longitudinal section obtained by axially cutting the cylindrical reaction apparatus of the sixth embodiment.

The structures of the reactive catalytic layers formed on the electrodes and the formation of the third reactive catalytic layer 21 composed of the pellet-type paraelectrics (or ferroelectrics) in the channel 19 of the tenth embodiment are identical with those of the previous embodiments except for a difference in the structures of the electrodes.

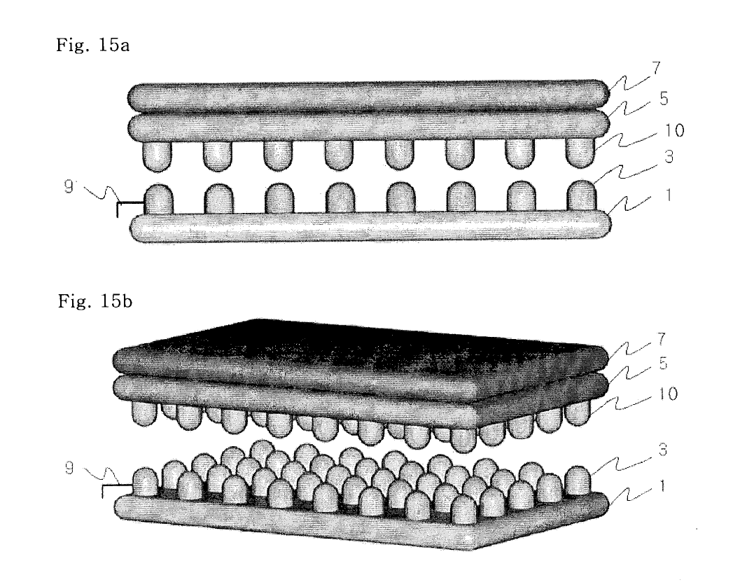

That is, as shown in FIG. 10, the plasma reaction apparatus comprises the first plate-type electrode 11, the second plate-type electrode 15 installed to face the first electrode 11 with a predetermined interval therebetween, the first and second reactive catalytic layers 13, 17 formed on the surfaces of the first and second electrodes 11, 15, respectively, and the third reactive catalytic layer 21 composed of the pellet-type paraelectrics or ferroelectrics and formed in a space between the first and second reactive catalytic layers 13, 17, i.e. in the channel 19.

At this time, the first and second reactive catalytic layers 13, 17 may have the laminated structure in which the amorphous insulation layers 13a, 17a and the crystalline dielectric layers 13b, 17b are sequentially stacked one above another, respectively, or may be constructed only by the amorphous insulation layers composed of material falling within the group consisting of glass, quartz, and Pyrex. Alternatively, they may be composed of only the paraelectrics such as Al₂O₃, ZrO₂ or TiO₂, or the ferroelectrics such as material falling within the BaTiO₃ group. Here, if the reactive catalytic layers are formed only by the crystalline dielectric layers, it is preferred that they have no porosity so that the water cannot come into contact with the first and second electrodes 11, 15 and their surfaces have an embossing texture, a pointed peak texture, or a smooth texture so that the discharge can easily occur.

According to the tenth embodiment of the present invention, when the third reactive catalytic layer 21 composed of the pellet-type paraelectrics (or ferroelectrics) is formed in the channel 19, the strength of a partial electric field applied to the water becomes larger than that in the case where only the water exists therein. Thus, much alkaline water, ozone water, or acid water can be obtained at lower power consumption.

Moreover, since the plasma light is generated in the reaction apparatus, the various bacilli such as bacteria and dysentery bacillus in the water can be treated, so that the quality of resultant drinking water can be improved. In addition, since the first and second electrodes 11, 15 are not exposed directly to the water, the electrode wear can be minimized and thus the electrodes can be used semi-permanently.

Although not shown in the figures, further various embodiments can be implemented by combining the structures and arrangements of the reactive catalytic layers. The descriptions of the structures and arrangements of the reactive catalytic layers in the sixth embodiment can be equally applied to the possible embodiments except for the descriptions of the structures of the electrodes.

Eleventh Embodiment

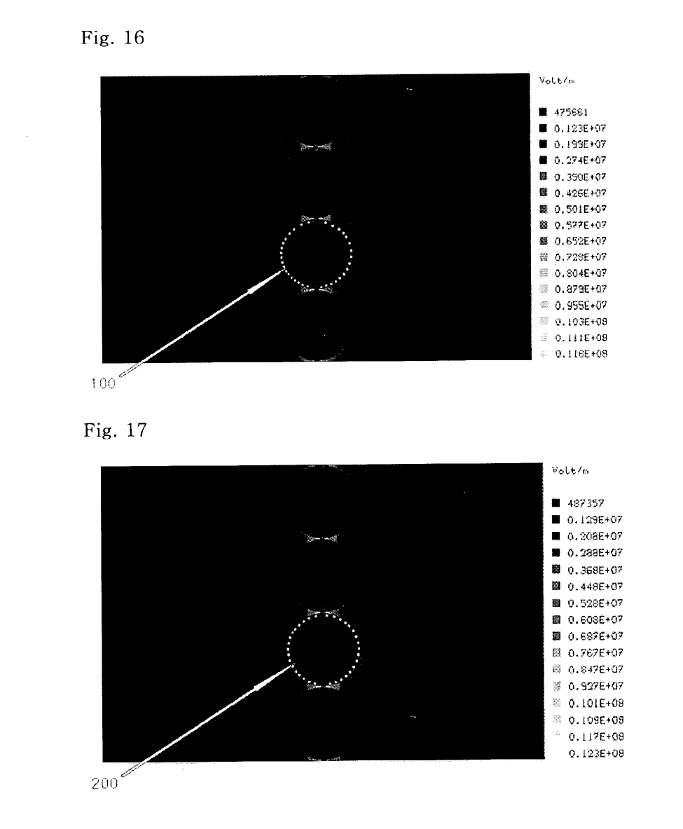

A plasma reaction apparatus according to an eleventh embodiment of the present invention has a honeycomb structure, as shown in FIG. 11. That is, as shown in the figure, a plurality of plate-type electrodes 101a, 101b and 101c are placed with a predetermined interval between the respective adjacent electrodes, reactive catalytic layers 103 constructed to have a net-shaped structure are formed in spaces between the respective adjacent electrodes, and holes 105 defined by the net-shaped structure are used as the channel.

At this time, it is also possible to dispose the pellet-type paraelectrics or ferroelectrics in the channel.

According to the eleventh embodiment of the present invention, when the direct current voltage, or any one of alternating or pulsed voltages having various frequencies is applied to the electrodes 101a, 101b and 101c, strong electric filed concentration occurs at portions where the water is in contact with the reactive catalytic layers 103 and then plasma resulting from the underwater discharge is generated. Consequently, the alkaline water, ozone water, or acid water can be more effectively produced.

Furthermore, when the pellet-type paraelectrics or ferroelectrics are disposed in the channel, the discharge can be generated at a much lower voltage and thus the discharge efficiency can be maximized. In addition, since the discharge has a non-thermal plasma discharge characteristic, the plasma reaction apparatus can be safely operated with higher reliability and accuracy resulting from the discharge control.

Hereinbefore, the plasma reaction apparatuses for the discharge in the water have been described. Plasma reaction apparatuses for discharge in oil will be briefly explained below.

First, the plasma reaction apparatuses for the discharge in the oil according to the present invention have the same structures as the plasma reaction apparatuses for the underwater discharge according to the previous embodiments. There is only a difference between them in that the discharge medium between the electrodes is oil instead of the water. Therefore, the descriptions of the structures of the plasma reaction apparatuses for the discharge in the oil will be omitted. Reaction phenomena in the plasma reaction apparatuses for the discharge in the oil according to embodiments will be focused on in their descriptions.

The plasma reaction apparatuses for the discharge in the oil can achieve a decrease in the molecular weight of the oil such as gasoline, kerosene, light oil, bunker C oil and waste oil, and thus, fuel gasification of various kinds of oils and waste oils can be finally accomplished.

The oil such as gasoline, kerosene, light oil and waste oil can be gasified so that it can be used as fuels for driving of a gas automobile and heating. When the light oil and the kerosene are treated using the plasma reaction apparatuses for the discharge in the oil according to the present invention, a gasoline automobile can be driven. The oil can be modified to minimize the amounts of generation of shoot, soot, volatile organic compounds (VOC), and hydrocarbons (HC).

Further, a molecular structure of the oil is excited by imparting electric energy thereto and then converted into bonding of hydrocarbons having low molecular weights which have been ionized or strongly activated, so that the automobile can be easily started using the treated oil even in winter.

In the plasma reaction apparatus for the discharge in the oil which has the structure shown in FIG. 1a according to the present invention, the strength of the electric field on the surface of the dielectrics is increased so that the plasma light is generated. Accordingly, when the discharge occurs, a stable discharge plasma state is obtained in the oil rather than the unstable streamer discharge. That is, since the stable discharge plasma state is made by means of a high electric field and a low current rather than the thermal discharge in the oil, the power consumption can be minimized.

Moreover, since the insulation material protects the electrodes, the electrode wear can be minimized and thus the electrodes can be used semi-permanently.

Meanwhile, although will be described later, the electrode may be configured in the form of a mesh, a surface, multiple lines or brush-type multiple needles. If an electrode except for the surface-type electrode is used, the electrode should be designed such that vibration due to electrode resonance upon occurrence of the discharge is small and the radius of curvature thereof is small.

In the plasma reaction apparatus for the discharge in the oil according to the present invention, the third reactive catalytic layer 21 composed of the pellet-type paraelectrics can be formed in the oil channel, as shown in FIG. 6.

That is, the first and second reactive catalytic layers 13, 17 constructed by the amorphous insulation layers 13a, 17a and the crystalline dielectric layers 13b, 17b are formed on the surfaces of the first and second electrodes 11, 15, respectively, and the third reactive catalytic layer 21 composed of the pellet-type paraelectrics (or ferroelectrics) is formed in the oil channel. Thus, the strength of a partial electric field applied to the oil is several dozen times as strong as that in the discharge using only the oil as the medium. Consequently, much hydrocarbon gas, hydrogen gas, and carbon gas can be produced in view of ionization of the oil and the amount of conversion per unit time.

Moreover, the plasma light is generated and ultraviolet rays generated at this time assist in decomposition of the oil in cooperation with the plasma energy in the oil. The disposition of the pellet-type paraelectrics or ferroelectrics in the oil channel can lower a starting voltage for the discharge.

On the other hand, the plasma reaction apparatus for the discharge in the oil according to the present invention may include the electrodes having such a parallel plate type configuration as that of the ninth embodiment. Alternatively, as shown in FIG. 10, the electrodes are formed to have the parallel plate type configuration and the pellet-type paraelectrics or ferroelectrics may be further disposed in the oil channel.

The plasma reaction apparatus for the discharge in the oil according to the present invention may be constructed to have the honeycomb structure as shown in FIG. 11.

As described above, the structures of the plasma reaction apparatuses for the discharge in the oil according to the present invention are identical with those of the plasma reaction apparatuses for the underwater discharge according to the previous embodiments.

Although the above descriptions are made in view of the structures of the plasma reaction apparatuses, the strength and distribution of the electric field will be explained hereinafter in consideration of the shapes of the electrodes, and the sizes and structures of the reactive catalytic layers depending on their materials.

Twelfth Embodiment

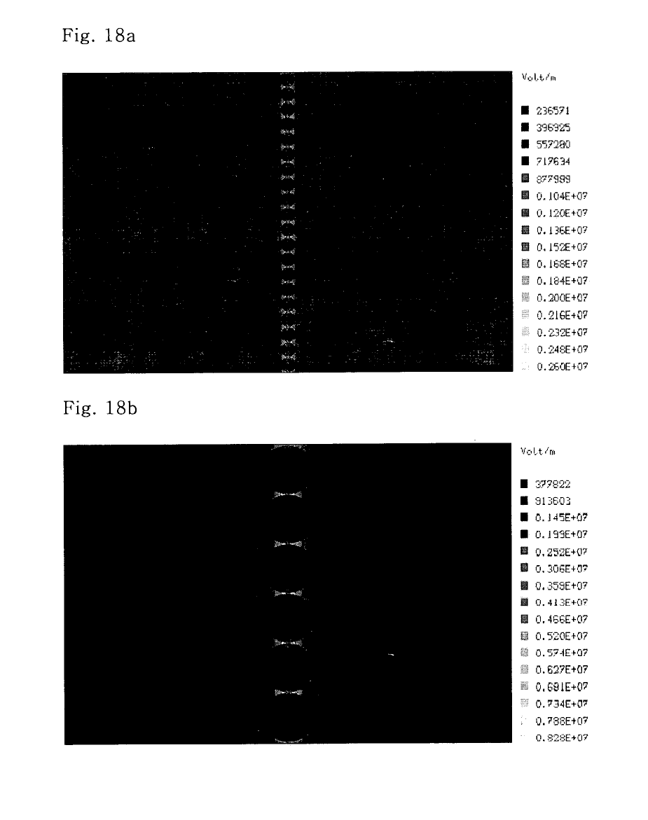

FIG. 12a shows an inner section of a plasma reaction apparatus according to a twelfth embodiment of the present invention, and FIG. 12b is a perspective view of the inner section.

As shown in the figures, the plasma reaction apparatus according to the twelfth embodiment of the present invention comprises first protrusion-type electrodes 3 formed on a dielectric layer 1, a plate-type discharging or reactive catalytic layer 5 formed to face the first electrodes 3, and a second electrode 7 formed on the discharging catalytic layer 5.

Here, the discharging catalytic layer 5 is composed of the paraelectrics, the ferroelectrics, or insulation material of which a surface is coated with a material having a discharging catalytic function such as titanium oxide (TiO2). The discharging catalytic layer may have a laminated structure in which an amorphous insulation layer and a crystalline dielectric layer are sequentially stacked one above another, or a single-layered structure constructed only by the amorphous insulation layer or the crystalline dielectric layer.

If the discharging catalytic layer 5 is constructed by the amorphous insulation layer, it is preferred that the insulation material is perfect insulation material falling within a group consisting of glass, quartz, and Pyrex which have dielectric constants within a range of a few to several hundreds.

The first protrusion-type electrodes 3 are arranged at a predetermined interval on the dielectric layer. A power supply line 9 is connected to one of the first electrodes so as to apply a voltage thereto. Each of the first electrodes 3 may be shaped in the form of a needle, a rod, a sphere or the like.

In the plasma reaction apparatus according to the twelfth embodiment of the present invention, even though the voltage is applied only to at least one of the first protrusion-type electrodes 3 formed on the dielectric layer 1, an electric field is spread along a surface of the reactive catalytic layer 5 installed to face the first electrodes 3, so that an entire discharging region is allowed to be a plasma discharge region and the discharge from glow discharge to arc discharge can occur.

Referring to FIGS. 13a and 13b, the discharge region is further expanded as compared with the twelfth embodiment since the reactive catalytic layer 5 is not in contact with but spaced apart from upper surfaces of the first electrodes 3 by a predetermined distance. The predetermined distance is preferably 0 to 2 mm.

Meanwhile, FIGS. 14a and 14b show a configuration in which dielectric structures 10 or metal electrodes are further added onto the discharging catalytic layer 5 to face the first electrodes 3, respectively. At this time, the dielectric structures 10 or metal electrodes take the shape similar to that of the first electrodes 3, and may be arranged to be in contact with the first electrodes 3, or may not be in contact with but spaced apart from the first electrodes 3 by a predetermined distance as shown in FIGS. 15a and 15b. Such a configuration has an advantage in that a larger discharge region can be ensured.

Thirteenth Embodiment

In a thirteenth embodiment, two plate-type electrodes are installed to face each other and pellet-type paraelectrics are disposed between the electrodes.

The pellet-type paraelectrics disposed between the electrodes are actually a discharging catalytic layer for maximizing the discharge efficiency therebetween. Even when the paraelectrics having dielectric constants within a range of a few dozens to several hundreds are used instead of the ferroelectrics, it is possible to obtain the discharge efficiency similar to that obtained in case of use of the ferroelectrics.

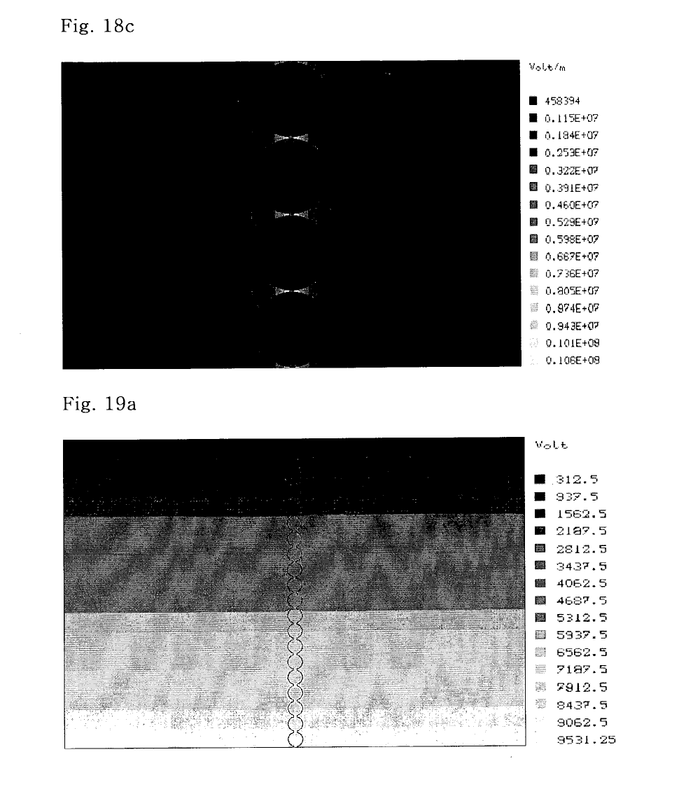

That is, as shown in FIG. 16, when the pellet-type paraelectrics 100 (dielectric constant=100) are disposed between the two electrodes (not shown), a maximum strength of the electric filed is 0.116E+08 V/m, as can be seen from the figure. When the ferroelectrics 200 (dielectric constant=3000) are disposed between the two electrodes as shown in FIG. 17, it can be seen from the figure that a maximum strength of the electric field is 0.121E+08 V/m. Therefore, it can be understood that even when the pellet-type paraelectrics 100 are used, it is possible to obtain the strength of the electric field substantially similar to that obtained in case of use of the ferroelectrics 200 which are expensive and difficult to be prepared into the pellet shape.

Moreover, upon use of the paraelectrics 100 instead of the ferroelectrics 200, adjustment of the size of the pellets of the paraelectrics 100 allows obtainment of the strength of the electric field identical with that obtained in the case of use of the ferroelectrics 200. This matter will be described in detail below.

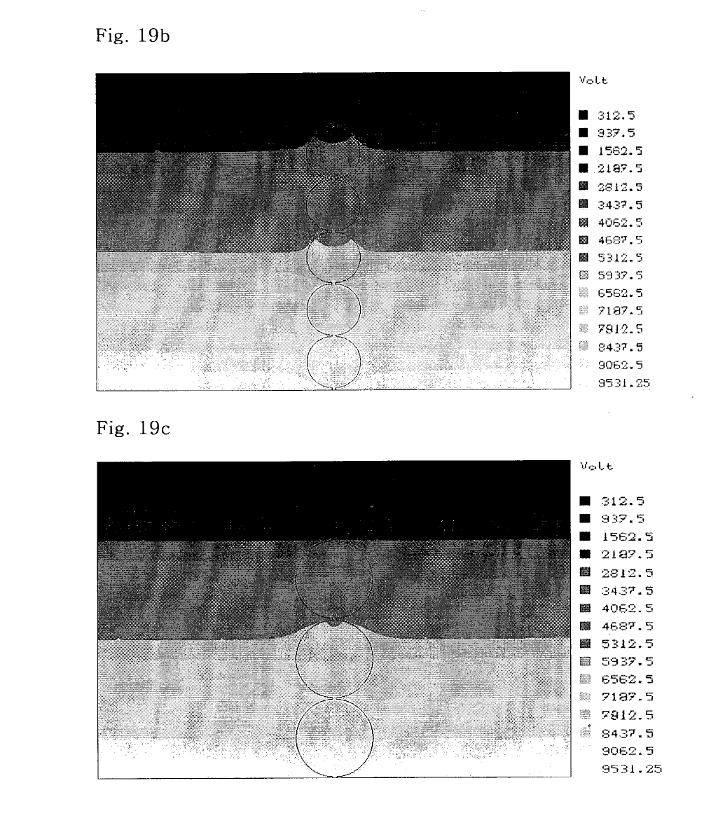

FIGS. 18a to 18c are sectional views showing the interior of the plasma reaction apparatus according to increases in the size of the pellets of the paraelectrics disposed between the two electrodes up to 1 mm, 3 mm and 5 mm, respectively.

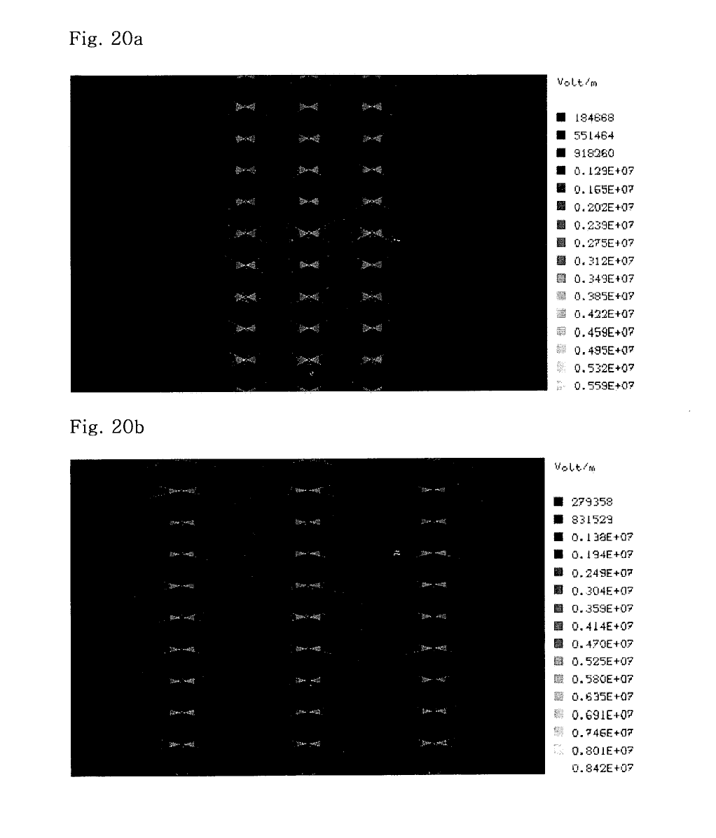

At this time, the pellets are made of paraelectrics having a dielectric constant of 100, the distance between the two electrodes is set to 20 mm. Equipotential lines by the pellet sizes in such cases are shown in FIGS. 19a to 19c.

It can be understood from the FIGS. 19a to 19c that there is a tendency for the potential to be saturated between adjacent pellets at the pellet size of about 5 mm. It can also be seen that the strength of the electric field is 0.260E+07 V/m at the pellet size of 1 mm, while it is 0.106E+08 V/m at the pellet size of 5 mm. Further, it can be understood that when the distance between the two electrodes is 20 mm, the size of the paraelectrics pellets disposed therebetween is preferably 2 to 10 mm, and most preferably about 5 mm, i.e. 3 to 5 mm.

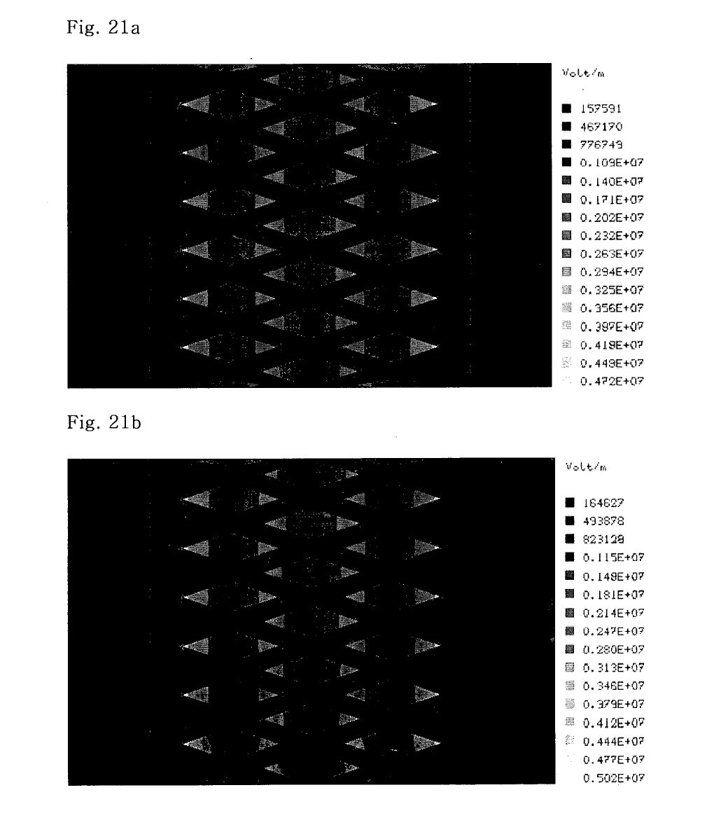

Meanwhile, FIGS. 20a and 20b show a case where the paraelectrics pellets formed between the two electrodes are shaped in the form of a rhombus. The structure of FIG. 20a is preferable in view of the treatment amount of the medium upon occurrence of the discharge, whereas the structure of FIG. 20b is preferable in view of increase in the strength of the electric field. This is because the strength of the electric field becomes stronger as the opposite surface areas of the rhombi of the paraelectrics pellets are wider.

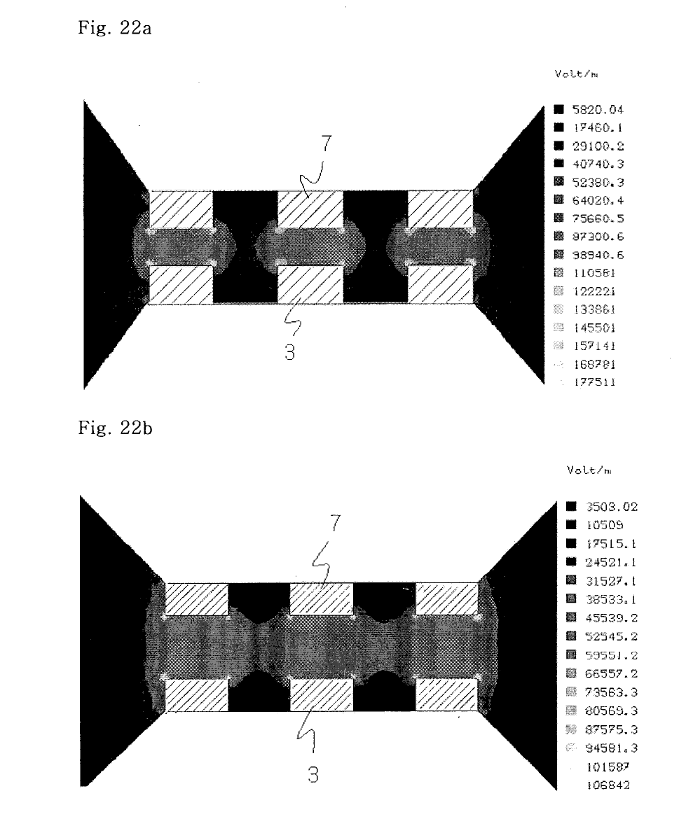

In the meantime, FIG. 21a shows the distribution of the electric filed in a case where the pellets of the paraelectrics having a dielectric constant of 100 are shaped in the form of a rhombus, and FIG. 21b shows the distribution of the electric filed in a case where the pellets of the ferroelectrics having a dielectric constant of 30000 are shaped in the form of a rhombus.

It can be understood from FIGS. 21a and 21b that assuming that the size of the rhombus and the distance between the two electrodes are the same, even though the paraelectrics having the dielectric constant that is three hundred times as small as that of the ferroelectrics having the dielectric constant of 30000 are used instead of the ferroelectrics, the maximum strength of the electric field reaches about 95% of that obtained in case of use of the ferroelectrics (ferroelectrics=0.502E+07; paraelectrics=0.475E+07). Therefore, it can be understood that even when the paraelectrics are utilized without using the ferroelectrics which are expensive and difficult to be prepared into the rhombus, the strength of the electric field substantially similar to that obtained in case of use of the ferroelectrics can be obtained.

With reference, although not shown in the figures, two plate-type electrodes arranged to face each other and the protrusion-type paraelectrics are formed on either one of the first and second electrodes, and it is possible that the perfect isolator such as glass is formed on the electrode comprising the paraelectrics.

At these structure, oil resolution or underwater discharge is become easy because an electric-field concentration is generated at peak part of said the protrusion-type paraelectrics.

Fourteenth Embodiment

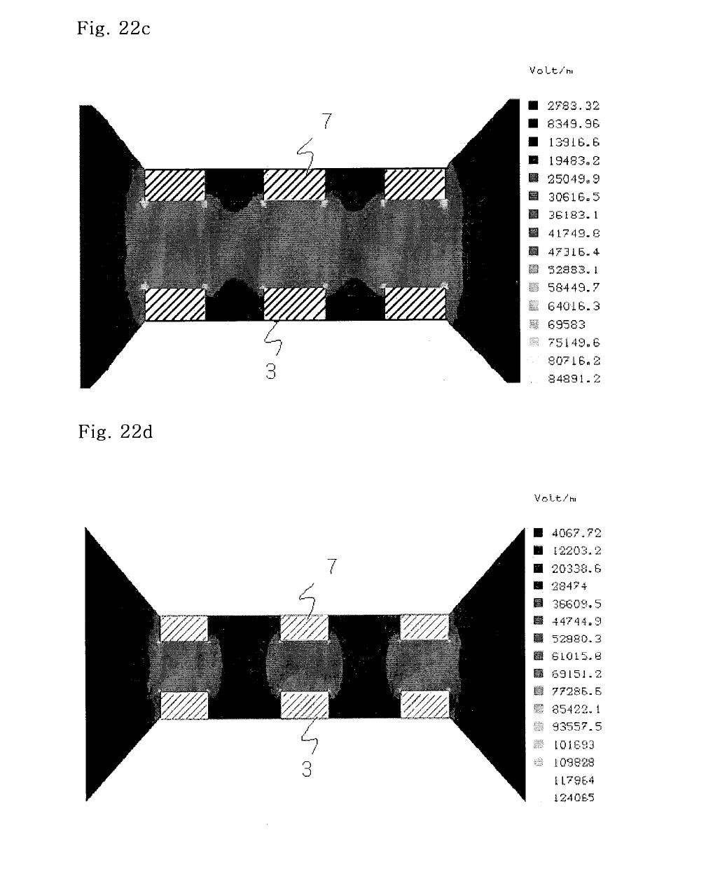

According to a fourteenth embodiment of the present invention, two electrodes installed to face each other are shaped in the form of protrusions. As shown in FIGS. 22a to 22d, the first and second electrodes 3, 7 in the form of the protrusions are opposite to each other with a discharge space interposed therebetween.

At this time, when the interval between the opposite electrodes is 1 mm, 2 mm and 3 mm in FIGS. 22a to 22c, respectively, the maximum strength of the electric field is 177,511 V/m, 106,842 V/m and 84,891.2 V/m in the configurations of FIGS. 22a to 22c, respectively. As a result, it can be understood that as the discharge space, i.e. the interval between the two electrodes, becomes smaller, the maximum strength of the electric field becomes larger.

As for the distribution of the electric field, it can be seen that the electric field is concentrated on edges of the electrodes. If the electric field is concentrated on the edges of the electrodes in such a way, the interference between the adjacent electrodes is increased. Thus, in order to reduce the interference between the electrodes, it is preferable to cause the distance between the adjacent equipotential electrodes to be larger than that between the two opposite electrodes 3, 7.

That is, when FIG. 22b is compared with FIG. 22d, the interference (designated by dotted lines in FIG. 22b) between the adjacent equipotential electrodes disappears in the configuration in which the distance between the adjacent equipotential electrodes is increased (FIG. 22d). It can also be seen that the maximum intensity of the electric field is increased from 106,842 V/m to 124,065 V/m.

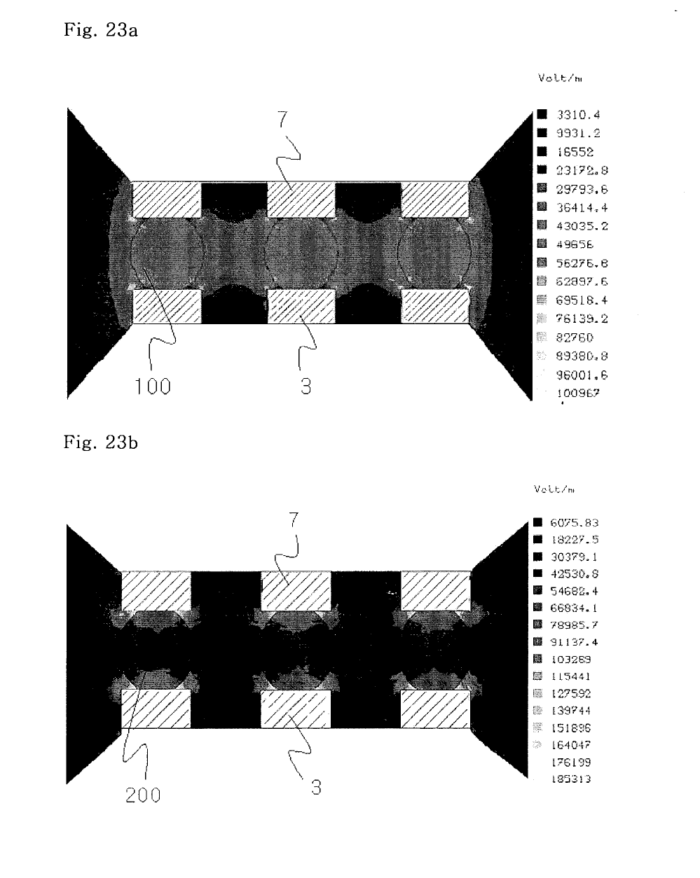

Meanwhile, FIG. 23a shows a case where the pellet-type paraelectrics (dielectric constant=10) 100 are disposed between the two electrodes. In a case where water as the medium exists between the two electrodes, it was intended to minimize the electrode wear due to electric field stress by disposing the paraelectrics between the two electrodes.

Such a configuration can minimize wear of the edges of the electrodes owing to further alleviation of the electric field stress, as compared with the configuration of FIG. 22a. By the disposing the paraelectrics, much more points on which an high electric field is distributed can be generated within a unit volume so that gas and liquid waste matter such as harmful gas, sewage and oil can be treated in large quantities. Therefore, the paraelectrics share the electric field stress so that a stable treatment effect can be obtained. Referring to FIG. 23b, there is shown a case where the pellets of the ferroelectrics (dielectric constant=3000) are formed between the two electrodes contrary to the case shown in FIG. 23a. In such a configuration, since a strong dielectric characteristic appears at points where the electrodes and the ferroelectrics meet each other, the electrode wear is further increased as compared with the configuration of FIG. 23a when the configuration of FIG. 23b is used for the underwater discharge.

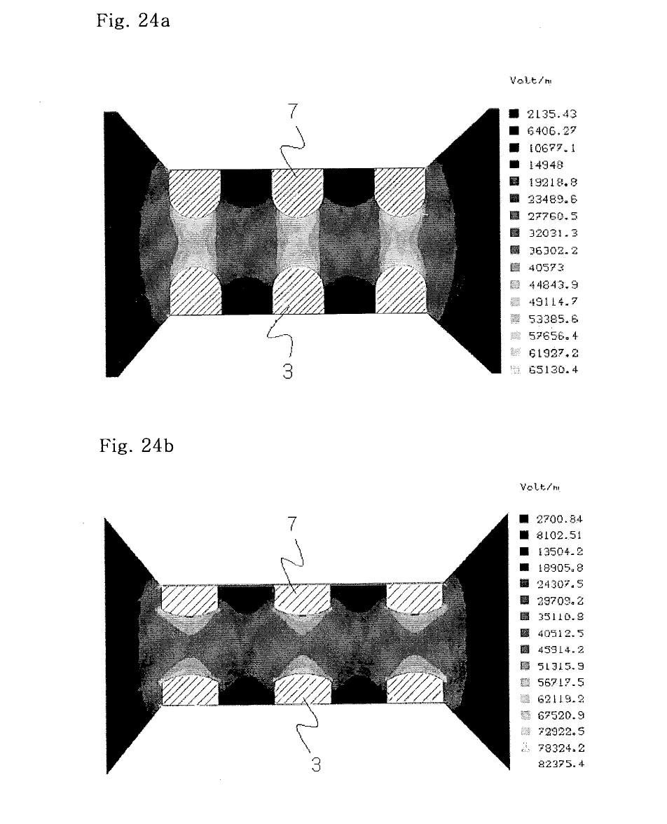

Meanwhile, FIGS. 24a and 24b are views showing optimal electrode shapes for minimizing the electrode wear. FIGS. 24a and 24b show cases where an angle formed between a center and both ends of an arc is 120° and 60°, respectively, wherein the distance between the two opposite electrodes is set to 2 mm.

In such a configuration, opposite surfaces of the two electrodes are rounded so that the electric field concentration on the edges of the electrodes can be relieved and thus the electrode wear can be minimized.

Although FIGS. 24a and 24b correspond to the cases where the angle formed between the center and both the ends of the arc is 120° and 60°, respectively, it is more preferred that the electrodes be designed such that an angle formed between a center and both ends of a central portion of the arc is 60° or lower, and at the same time, an angle formed between a center and both ends of each end portion of the arc is 120° or higher.

Fifteenth Embodiment

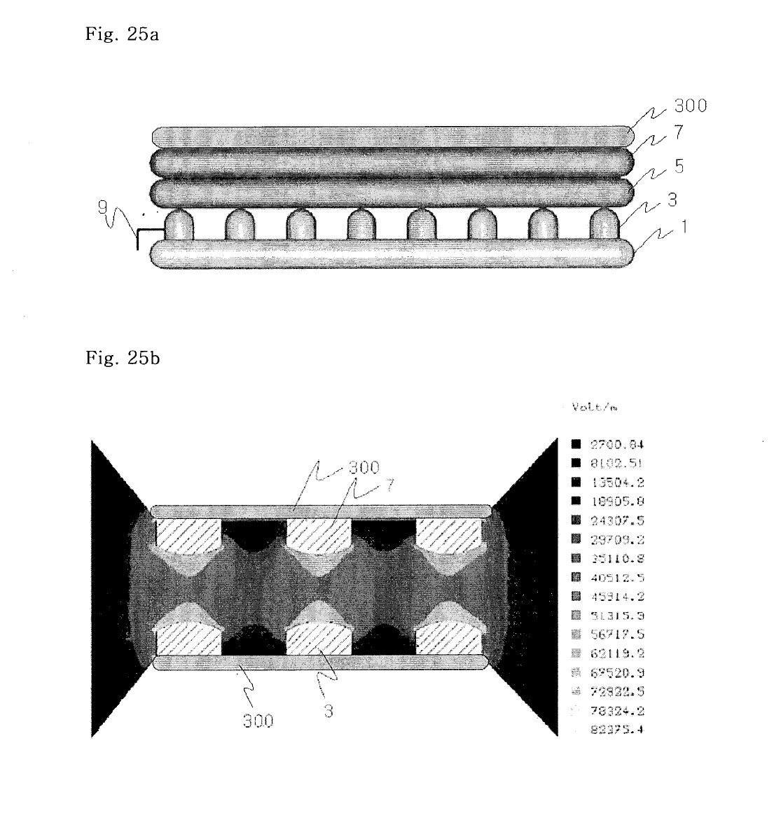

According to a fifteenth embodiment of the present invention, a magnet is formed on a rear surface of at least one of the opposite electrodes. FIGS. 25a and 25b show examples of this embodiment. Referring to FIG. 25a, there is a configuration in which a magnet 300 is installed on a rear surface of the second electrode 7. However, an additional magnet may also be installed on a rear surface of the dielectric layer 1. If the magnets are installed on both the rear surfaces of the dielectric layer 1 and the second electrode 7, the magnets should be installed to have the same polarity so that a magnetic field by the two magnets is generated in a direction perpendicular to that of the electric field.

Referring to FIG. 25b, there is shown a configuration in which the magnets are installed on rear surfaces of the first and second electrodes 3, 7. However, the magnet may be installed on the rear surface of only one of the first and second electrodes 3, 7. In the configuration shown in FIG. 25b, the two magnets 300 installed on the rear surfaces of the first and second electrodes 3, 7 are placed to have the same polarity.

The installation of the magnet 300 on the rear surface of at least one of the first and second electrodes 3, 7 in the fifteenth embodiment of the present invention utilizes a motion principle of a charged particle within an electromagnetic field.

In general, a motion of a charge in a space where the electric field and the magnetic field exist together is expressed as the following formula:

$$m \frac{ⅆ {v}^{->}}{ⅆ t} = Ze ( {E}^{->} \times {V}^{->} \times {B}^{->} )$$

where \vec{E} is the electric field, \vec{B} is the magnetic field, m is a mass of the charge, Ze is the quantity of charge, and \vec{V} is a velocity of the charge.

The above formula is the Lorentz equation. If the charge is placed in a space where only the electric field exists, the equation is expressed as the following formula:

$$m \frac{ⅆ {v}^{->}}{ⅆ t} = Ze ( {E}^{->} )$$

If there is no electric field and only the magnetic field is constant with time, the equation becomes the following formula:

$$m \frac{ⅆ {v}^{->}}{ⅆ t} = Ze ( {V}^{->} \times {B}^{->} )$$

This means that although the charge is simultaneously subjected to respective forces resulting from the electric and magnetic fields in the space where the electric and magnetic fields exist, the forces (energy) independently exert influence on the charge.

The motion of the charged particle in the magnetic field is made by composition of directional vectors for two kinds of kinetic energy for producing a constant velocity motion parallel with the magnetic field \vec{B} and a uniform circular motion of projection of the charge onto a plane perpendicular to the magnetic field \vec{B}. With the composition of the two forces, the charge performs a spiral motion in such a manner that it rotates while advancing in a direction of the electric field.

Considering an equilibrium relationship between the Lorentz force perpendicular to the magnetic field \vec{B} and a centrifugal force, the following formula is established:

maω_{c}²=|Z|eV_{L}B

$$∴ {ω}_{c} = \frac{\vert Z \vert eB}{m}$$

where ω_{c} is an angular frequency of the circular motion, V_{L}(=aω_{c}) is the magnitude of a component \vec{V}_{L} of the velocity \vec{V} perpendicular to the magnetic field \vec{B}, a is a radius of the circular motion, and B is the magnitude of the magnetic field \vec{B}.

The angular frequency ω_{c} is generally called a cyclotron frequency or Lamor frequency and is determined only based on the kind of the particle and the strength of the magnetic field. Further, the radius of the circular motion a can be expressed as the following formula:

$$a = \frac{{V}_{L}}{{ω}_{c}} = \frac{{mV}_{L}}{\vert Z \vert eB}$$

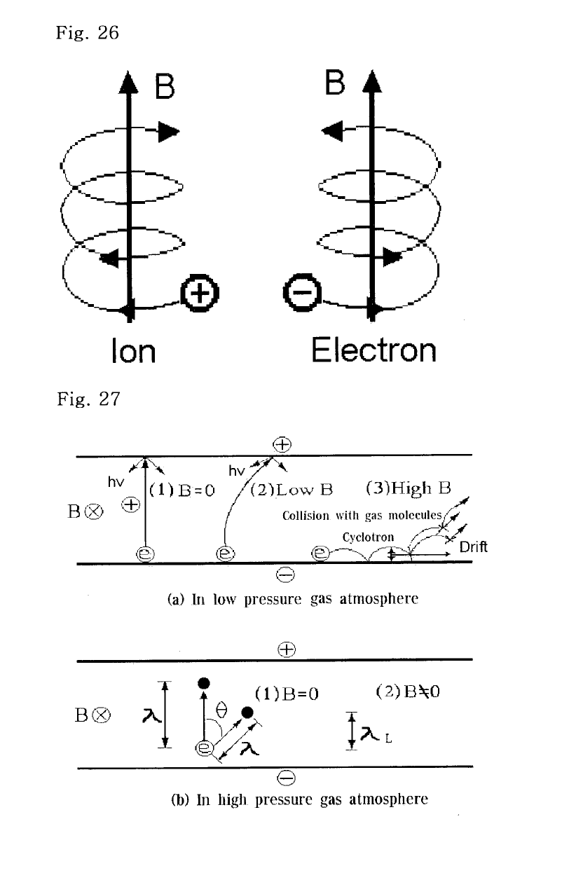

The radius is called a spiral radius or Lamor radius. As for a spiral direction, if the magnetic field is directed upward, an electron (−) rotates leftward whereas a positive ion rotates rightward as shown in FIG. 26.

Meanwhile, in connection with the magnetic filed, when the particle is not subjected to an external force, the center of the spiral motion moves along magnetic lines of force. On the contrary, if an external force is applied to the particle, the center of the spiral motion also moves in a direction perpendicular to the magnetic lines of force and has a velocity perpendicular to the magnetic field \vec{B} and the external force \vec{F}.

In the meantime, if an electron moves in a high pressure gas atmosphere in which electric and magnetic fields exist and loses its momentum through collision with gas molecules of the gas atmosphere vₘ times per second, a motion equation of the electron in such a case can be expressed as the following formula that is called Langevin equation:

$$m \frac{ⅆ {v}^{->}}{ⅆ t} = - e ( {E}^{->} + {v}^{->} \times {B}^{->} ) - m {v}^{->} {v}_{m}$$

where m is a mass of the electron, \vec{v} is a velocity of the electron, and vₘ is a momentum-conversion collision frequency. If vₘ=0, the above formula becomes a momentum equation of the electron under vacuum.

When the magnetic field perpendicular to the electric field is applied to the parallel plate type electrode configuration, a motion trajectory of the electron can be expressed as shown in FIG. 26.

As shown in FIG. 27, the electron starting from a cathode reaches an anode without colliding with the gas molecules if the magnetic field \vec{B} is weak in a low pressure gas atmosphere, whereas it performs the cyclotron motion in the same manner as a case (3) in FIG. 27(a) if the magnetic field \vec{B} is strong.

Since the electron starting from the cathode is returned back to the cathode if the cyclotron radius a(=2mE/eB²) is smaller than a distance between the electrodes, the effects of the electron is substantially lowered. If the cyclotron motion continues, collision ionization due to collision with remaining gas molecules occurs, and thus, the effects of ionization collision are observed.

On the other hand, in a high pressure gas atmosphere, since the electron collides with the gas molecules before completion of the cyclotron motion, a moving distance of the electron in the direction of the electric field during a mean free path is shortened as the magnetic field \vec{B} becomes stronger. Therefore, the application of the magnetic field \vec{B} induces an effect of increase in gas pressure in view of energy that the electron obtains from the electric field.

In this connection, the fifteenth embodiment of the present invention applies the motion principle of the charged particle in the electromagnetic field to the plasma reaction apparatus. Consequently, the discharge stress due to entrance and exit of the charged particle at the surface of the paraelectrics or at a position where the dielectrics meets a surface of a discharge tube or electrode of the reaction apparatus can be considerably reduced and thus the life of the electrode can be prolonged.

Furthermore, since the discharge region in the reaction apparatus becomes wider as compared with a case where only the electric field exists, discharge stability of the reaction apparatus can be improved. Thus, the power consumption can be lowered and the discharge efficiency can be enhanced.

Sixteenth Embodiment

According to a sixteenth embodiment of the present invention, the first and second electrodes are formed to have the parallel plate type electrode configuration and at least one of the two electrodes is provided with the magnet at a rear surface thereof.

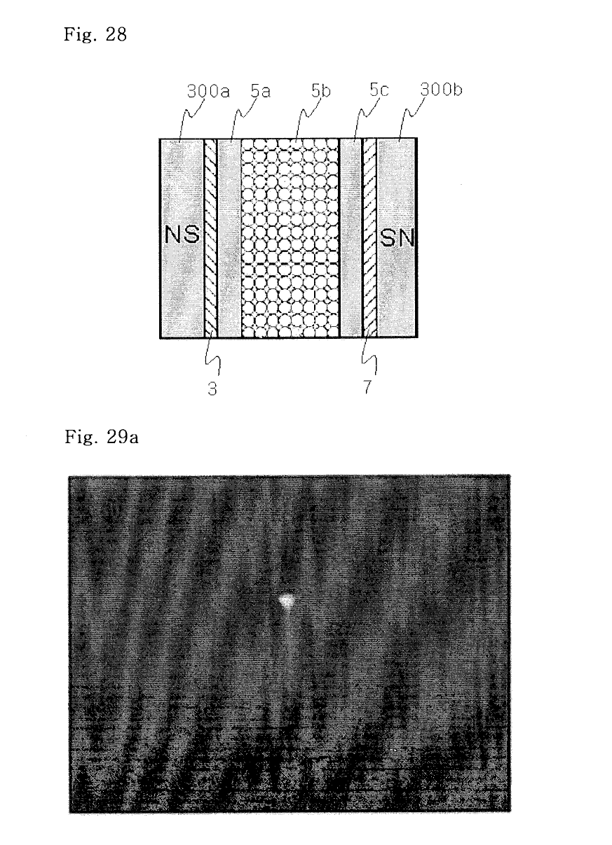

As shown in FIG. 28, a plasma reaction apparatus according to the sixteenth embodiment of the present invention comprises plate-type first and second electrodes 3, 7 installed to face each other with the discharge region interposed therebetween, first and second reactive catalytic layers 5a, 5b formed on surfaces of the electrodes facing the discharge region, respectively, a pellet-type third reactive catalytic layer 5c formed in the discharge region between the first and second reactive catalytic layers 5a, 5b, and the magnet 300 formed on at the rear surface of at least one of the first and second electrodes 3, 7. As one example of this embodiment, first and second magnets 300a, 300b are formed on the rear surfaces of the first and second electrodes 3, 7, respectively.

At this time, the first and second reactive catalytic layers 5a, 5b may have the laminated structures in which the amorphous insulation layers and the crystalline dielectric layers are sequentially stacked one above another, or at least one of the layers may be constructed by the amorphous insulation layer or the crystalline dielectric layer. The amorphous insulation layer is composed of insulation material having no porosity such as glass, quartz, and Pyrex. The crystalline dielectric layer is preferably composed of the paraelectrics such as Al₂O₃, ZrO₂ or TiO₂, or the ferroelectrics such as material falling within a BaTiO₃ group.

Platinum (Pt) is used as the material for composing the first and second electrodes 3, 7 to which a direct current source, or any one of alternating or pulsed sources having various frequencies is applied.

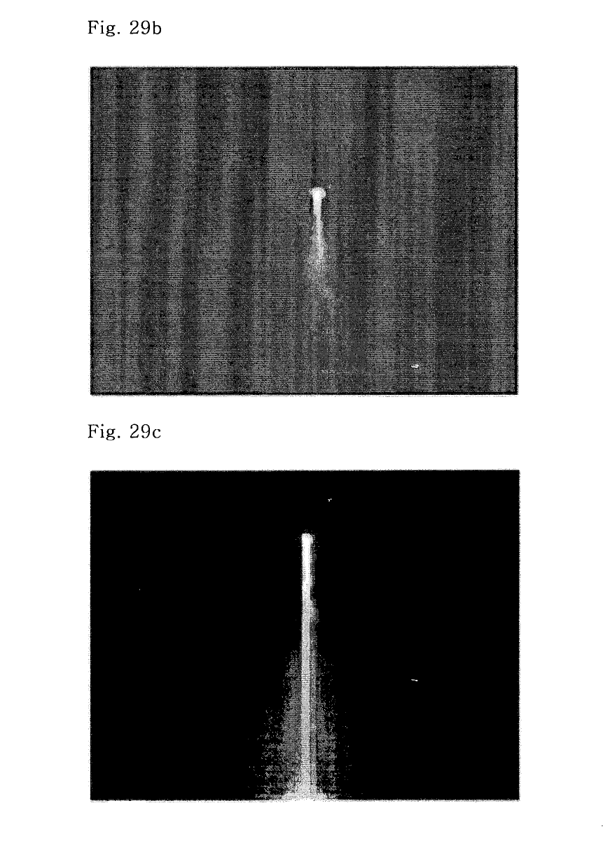

In such a configuration, the electric field is generated between the first and second electrodes 3, 7 and the magnetic field is generated in a direction perpendicular to the electric field. As can be seen from FIGS. 29a to 29d, when the magnetic field is applied to the configuration in addition to the electric field, stronger discharge can occur as compared with the case where only the electric field is applied thereto.

FIG. 29a shows a discharge pattern of the discharge region at a voltage of 10 kV when the magnetic field is not applied, and FIG. 29b shows a discharge pattern of the discharge region when the magnetic field is applied under the same voltage as FIG. 29a. FIG. 29c shows a discharge pattern of the discharge region at a voltage of 15 kV when the magnetic field is not applied, and FIG. 29b shows a discharge pattern of the discharge region when the magnetic field is applied under the same voltage as FIG. 29c.

According to the sixteenth embodiment, since the surfaces of the first and second electrodes 3, 7 are formed with the first and second reactive catalytic layers 5a, 5b having the laminated structures in which the amorphous insulation layers and the crystalline dielectric layers are sequentially stacked one above another, or the surface of at least one of the first and second electrodes 3, 7 is formed with the first or second reactive catalytic layer 5a or 5b composed of the amorphous insulation material or crystalline dielectrics, and the magnetic field is applied in the direction perpendicular to the electric field, as described above, more plasma light is generated in the discharge region and the first and second electrodes 3, 7 are covered with the insulation materials not to be in direct contact with the medium, thereby minimizing the electrode wear.

Seventeenth Embodiment

The previous embodiments relate to the plasma reaction apparatuses having the parallel plate type electrode configuration in which both the electrodes are the plate-type or one of the electrodes is the plate-type and the other electrode takes the shape of protrusions formed to face the plate-type electrode. However, a plasma reaction apparatus to be described hereinafter has a cylindrical electrode configuration instead of the parallel type electrode configuration.

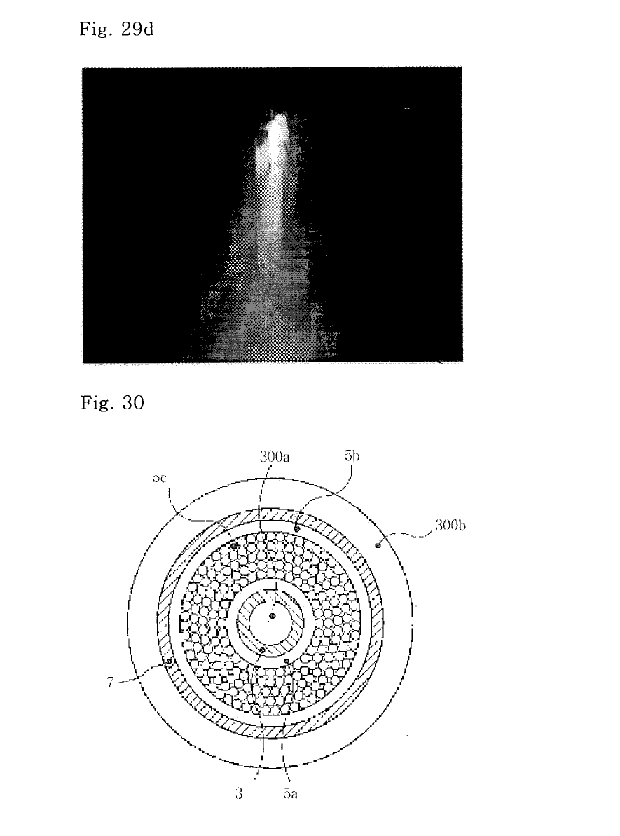

FIG. 30 is a front view of a plasma reaction apparatus according to a seventeenth embodiment of the present invention. The plasma reaction apparatus according to the seventeenth embodiment comprises the first cylindrical magnet 300a at the center of the apparatus, the first electrode 3 formed along an outer periphery of the first magnet 300a, the first reactive catalytic layer 5a formed along an outer periphery of the first electrode 3, the second reactive catalytic layer 5b formed to surround the first reactive catalytic layer 5a with a predetermined space (discharge region) interposed therebetween, the second electrode 7 formed along the second reactive catalytic layer 5b, the second magnet 300b formed along an outer periphery of the second electrode 7, and the pellet-type third reactive catalytic layer 5c formed in the discharge region between the first and second reactive catalytic layers 5a, 5b.

At this time, it is preferred that the magnetic field applied by the first and second magnets 300a, 300b be applied in the direction perpendicular to the electric field between the first and second electrodes 3, 7. To this end, each of the first and second cylindrical magnets 300a, 300b is constructed such that one longitudinal half thereof has an N-polarity and the other longitudinal half has an S-polarity, and the first and second magnets 300a, 300b are disposed to have the same polarity configuration as each other.

Meanwhile, although FIG. 30 shows the configuration in which the first reactive catalytic layer 5a is formed along the outer periphery of the first electrode 3 and the second reactive catalytic layer 5b is formed along the inner periphery of the second electrode 7, it is also possible to form only one of the first and second reactive catalytic layers 5a, 5b.

Further, the first and second reactive catalytic layers 5a, 5b may have the laminated structure in which the amorphous insulation layers and the crystalline dielectric layers are sequentially stacked one above another, or the single-layered structure constructed by the amorphous insulation layer or the crystalline dielectric layer. Here, the crystalline dielectric layer is preferably composed of the paraelectrics such as Al₂O₃, ZrO₂ or TiO₂, or the ferroelectrics such as material falling within a BaTiO₃ group. If only the crystalline dielectric layer is formed directly on the respective electrodes without forming the amorphous insulation layer thereon, the crystalline dielectric layer may be composed of any materials which have no porosity not to allow the electrodes to come into contact with the water and of which surfaces facilitate the discharge.

In the plasma reaction apparatus according to the seventeenth embodiment of the present invention, since the pellet-type paraelectrics or ferroelectrics are disposed in the discharge region, the strength of a partial electric field applied to the medium is several dozen times as strong as that in the discharge using only the water, oil or gas as the medium. Thus, in case of the underwater discharge, much alkaline water, ozone water, or acid water can be obtained at much lower power consumption in view of ionization of the water and productivity per unit time.

Moreover, the plasma light is generated in the reaction apparatus by means of the formation of the first, second and third reactive catalytic layers 5a, 5b and 5c. The ultraviolet rays generated at this time are useful to treat various bacilli such as bacteria and dysentery bacillus together with plasma energy in the medium, so that the quality of resultant drinking water can be improved.

Furthermore, since the first and second reactive catalytic layers 5a, 5b completely separate the first and second electrodes 3, 7 from the medium, the electrode wear can be minimized and thus the electrodes can be used semi-permanently.

In addition, when the plasma reaction apparatus of the present invention is used as an underwater-discharge plasma reaction apparatus for generating washing water, electrolyzed water which has passed through the interior or discharge region of the reaction apparatus is drained to the exterior of the reaction apparatus while establishing a charge separation layer in a short time. Thus, the electrolyzed water is charged into negative charges and positive charges which in turn are separated, by using a diaphragm or a charging plate for a direct current source and a diaphragm. At this time, the diaphragm is installed in the plasma reaction apparatus or a rear end of the reaction apparatus where the washing water is drained. In order to maintain the separation state of the charges separated by the diaphragm, an electrode plate having a polarity opposite to that of the charges is installed at the rear end of the reaction apparatus.

When the electrolyzed water is separated into acid electrolyzed water and alkaline electrolyzed water by using the charging plate and the diaphragm in such a way and the acid and alkaline electrolyzed water are then separately utilized, more effective washing can be made.

Here, the diaphragm can be made of ceramic having large porosity (amorphous glass fibers and crystalline ceramic), clothes, electrochemically-stable porous polymer fibers (urethane, Teflon, reinforced plastic), or the like. The diaphragm has a structure having pores enough to allow the charged particles to pass therethrough.

Moreover, in order to enhance the washing efficiency by means of the washing water, it is possible to use an additive such as sodium bicarbonate (NaHCO₃), sodium carbonate (Na₂CO₃), salt (NaCl), compounds falling within a sodium hydroxide (NaOH) group, barium hydroxide (Ba(OH)₂), or potassium carbonate (K₂CO₃).

As described above, the plasma reaction apparatus for the discharge in both the water and oil has the following effects.

When the plasma reaction apparatus is used for the discharge in the water (underwater discharge), the reactive catalytic layers are formed so that the discharge efficiency is maximized and a lot of ozone water, acid water or alkaline water can be produced at low power consumption. Further, when air or oxygen in the form of bubbles is injected into the reaction apparatus in a state where a voltage is applied to the electrodes, the triple point among the injected air or oxygen, the dielectrics and the water is obtained, so that a strong electric field is generated and thus a lot of ozone water, acid water or alkaline water can be produced.

Since the electrodes do not come into direct contact with the water, the electrode wear can be minimized and used semi-permanently.

The plasma generated during the underwater discharge can eliminate various bacilli such as bacteria and dysentery bacillus and thus enhance the quality of resultant drinking water.

When the plasma reaction apparatus is used for the discharge in the oil, the reaction apparatus can achieve a decrease in the molecular weight of heating oil such as gasoline, kerosene, light oil, and bunker C oil, and thus, various kinds of oils and waste oils can be gasified to be finally used as fuel.

That is, the oil such as gasoline, kerosene, light oil and waste oil can be gasified so that it can be used as fuels for driving of a gas automobile and heating.

Since a stable plasma discharge pattern in the form of glow is obtained instead of corona or streamer discharge, a lot of oil can be decomposed at low power consumption.

A molecular structure of the oil is excited by imparting electric energy thereto and then converted into bonding of hydrocarbons having low molecular weights which have been ionized or strongly activated, so that the automobile can be easily started using the treated oil even in winter.

When the light oil and the kerosene are treated using the plasma reaction apparatus of the present invention, a gasoline automobile can be driven and it is possible to minimize the amounts of generation of shoot and soot by using the oil having low molecular weight.

If the plasma reaction apparatus for the discharge in the oil according to the present invention is applied to oil refining towers of oil refining companies in Korea and the other foreign countries which perform separation of oils based on differences in specific gravities thereof depending on temperature, much more high-grade gas and oil can be produced and processed.

As for animal liquid oils and fats, fuel and gas for heating can be produced by using the electrical discharge energy.

Further, the two electrodes are configured into optimal shapes for minimizing the electrode wear so that the lives of the electrodes can be prolonged. The plasma reaction apparatus is effective in decomposition and purification of harmful liquid materials including washing, elimination of virus, and neutralization of chemical waste matters.

Moreover, dioxin generated from combustion in an incinerator, volatile organic compounds, and non-degradable CFC for use in semiconductor processes and refrigerators can be effectively treated.

Although the present invention has been described with respect to the preferred embodiments, various changes and modifications can be made thereto and various equivalents can be employed therein. It will be apparent that the embodiments can be properly modified and the modified embodiments can also be equally applied. Therefore, the above descriptions do not limit the scope of the invention defined by the appended claims.

What is claimed is:

1. A plasma reaction apparatus for causing discharge to occur by using any one of water, oil and gas as a medium and applying a voltage to two electrodes disposed in a reactor of the apparatus, comprising:
a reactor body having an inlet and an outlet for the medium;
first and second electrodes formed on both sides with a discharge region interposed therebetween in the reactor body; and
a reactive catalytic layer formed on at least one of the first and second electrodes facing the discharge region.

2. The apparatus as claimed in claim 1, wherein the reactive catalytic layer has a laminated structure constructed by sequentially stacking an amorphous insulation layer and a crystalline dielectric layer one above another, or a single-layered structure composed of only any one of the amorphous insulation layer and the crystalline dielectric layer.

3. The apparatus as claimed in claim 1, further comprising an additional reactive catalytic layer composed of pellet-type paraelectrics or ferroelectrics in the discharge region.

4. A plasma reaction apparatus for causing discharge to occur by using any one of water, oil and gas as a medium and applying a voltage to two electrodes disposed in a reactor of the apparatus, comprising:
a reactor body having an inlet and an outlet for the medium;
first and second electrodes installed with a discharge region interposed therebetween in the reactor body; and
first and second reactive catalytic layers formed on the first and second electrodes facing the discharge region, respectively.

5. The apparatus as claimed in claim 4, further comprising a third reactive catalytic layer in the discharge region.

6. The apparatus as claimed in claim 4, wherein each of the first and second reactive catalytic layers has a laminated structure constructed by sequentially stacking an amorphous insulation layer and a crystalline dielectric layer one above another, or a single-layered structure composed of only any one of the amorphous insulation layer and the crystalline dielectric layer.

7. The apparatus as claimed in claim 4, wherein one of the first and second reactive catalytic layers has a laminated structure constructed by sequentially stacking an amorphous insulation layer and a crystalline dielectric layer one above another, and the other of the first and second reactive catalytic layers has a single-layered structure composed of only any one of the amorphous insulation layer and the crystalline dielectric layer.

8. The apparatus as claimed in claim 4, wherein the first electrode takes the shape of a cylinder, and the second electrode is constructed to surround the first electrode with the discharge region interposed therebetween.

9. The apparatus as claimed in claim 4, wherein the first and second electrodes are formed to have a parallel plate-type configuration.

10. The apparatus as claimed in claim 5, wherein the third reactive catalytic layer takes the shape of pellets made of paraelectrics or ferroelectrics.

11. The apparatus as claimed in claim 6, wherein the crystalline dielectric layer is made of one of ZrO₂, TiO₂, Al₂O₃, and BaTiO₃ and has a dielectric constant within a range of a few to several hundreds.

12. A plasma reaction apparatus for causing discharge to occur by using any one of water, oil and gas as a medium and applying a voltage to two electrodes disposed in a reactor of the apparatus, comprising:
a reactor body having an inlet and an outlet for the medium;
a plurality of electrodes arranged at a constant interval in the reactor body;
reactive catalytic layers having a plurality of pores and formed between the respective adjacent electrodes; and
pellet-type paraelectrics or ferroelectrics disposed within the pores.

13. The apparatus as claimed in claim 12, wherein the reactive catalytic layers are constructed by sequentially stacking amorphous insulation layers and crystalline dielectric layers one above another, or have surfaces composed of crystalline dielectrics having an embossing texture or a pointed peak texture.

14. A plasma reaction apparatus for causing discharge to occur by using any one of water, oil and gas as a medium and applying a voltage to two electrodes disposed in a reactor of the apparatus, comprising:
first protrusion-type electrodes formed on a plate-type paraelectric layer;
a second plate-type electrode formed to face the first electrodes; and
a plate-type reactive catalytic layer formed on the second electrode to face the first electrodes.

15. The apparatus as claimed in claim 14, wherein the reactive catalytic layer is composed of one of paraelectrics and ferroelectrics, or of insulation material of which a surface is coated with a photocatalyst including titanium oxide.

16. The apparatus as claimed in claim 14, wherein a power supply line is connected to one of the first protrusion-type electrodes for supplying electric power thereto.

17. The apparatus as claimed in claim 14, wherein the first electrodes and the reactive catalytic layer are in contact with or spaced apart at a predetermined distance from each other.

18. The apparatus as claimed in claim 14, wherein dielectric structures or metal electrodes are further provided onto the reactive catalytic layer on a side opposite to the second electrode.

19. A plasma reaction apparatus for causing discharge to occur by using any one of water, oil and gas as a medium and applying a voltage to two electrodes disposed in a reactor of the apparatus, comprising:
a reactor body having an inlet and an outlet for the medium;
first and second electrodes installed to face each other with a discharge region interposed therebetween in the reactor body; and
a pellet-type paraelectric layer formed in the discharge region between the first and second electrodes.

20. The apparatus as claimed in claim 19, wherein the size of the paraelectric pellets is 2 to 10 mm in diameter.

21. The apparatus as claimed in claim 19, wherein the first and second electrodes are arranged to have a parallel plate-type configuration.

22. The apparatus as claimed in claim 19, wherein the first and second electrodes are constructed by protrusions of which opposite surfaces are rounded and which are arranged at a predetermined interval.

23. The apparatus as claimed in claim 22, wherein the first and second electrodes are rounded within an angular range of 60° to 120° formed between both ends of the round and a center obtained by intersection of lines extending from both the ends thereof.

24. The apparatus as claimed in claim 19, wherein a magnet is further provided on a rear surface of at least one of the first and second electrodes.

25. The apparatus as claimed in claim 19, wherein surfaces of the first and second electrodes which face the discharge region are further provided with first and second reactive catalytic layers, respectively.

26. The apparatus as claimed in claim 19, wherein a diaphragm is further provided in the discharge region or the medium outlet of the reactor body for separating charged particles of the medium which has passed through the discharge region.

27. The apparatus as claimed in claim 26, wherein the diaphragm is made of ceramic having high porosity and including amorphous glass fibers and crystalline ceramic, clothes, and electrochemically-stable porous polymer fibers including urethane, Teflon, and reinforced plastic.
